(19) United States
(12) Patent Application Publication
(10) Pub. No.: US 2025/0355180 A1
(43) Pub. Date: Nov. 20, 2025

(54) SEMICONDUCTOR STRUCTURE INCLUDING OPTICAL DEVICE AND METHOD FOR MANUFACTURING THE SAME

(71) Applicant: TAIWAN SEMICONDUCTOR MANUFACTURING COMPANY, LTD., Hsinchu (TW)

(72) Inventors: Tai-Chun HUANG, Hsinchu (TW); Stefan RUSU, Hsinchu (TW)

(21) Appl. No.: 19/287,498

(22) Filed: Jul. 31, 2025

Related U.S. Application Data
(63) Continuation of application No. 18/322,921, filed on May 24, 2023.
(60) Provisional application No. 63/478,624, filed on Jan. 5, 2023.

(51) Int. Cl. G02B 6/124; G02B 6/12; G02B 6/13; H10F 30/223; H10F 39/10; H10F 71/00; H10F 77/122; H10F 77/40

(52) U.S. Cl. CPC G02B 6/124; G02B 6/12004; G02B 6/13; H10F 30/223; H10F 39/103; H10F 71/1212; H10F 77/122; H10F 77/413; G02B 2006/12107

(57) ABSTRACT

A semiconductor structure includes a waveguide structure on a substrate. The waveguide structure includes a first protrusion having a first dopant type; a first lower portion having the first dopant type; a second lower portion having a second dopant type, wherein the second dopant type is different from the first dopant type, and an interface of the first lower portion and the second lower portion defines a PN interface; and a second protrusion having the second dopant type. The semiconductor structure further includes a photoelectric material proximate the PN interface, wherein the photoelectric material extends above the PN interface.

### CROSS-REFERENCE TO RELATED APPLICATIONS

This application is a continuation of U.S. application Ser. No. 18/322,921, filed May 24, 2023, which claims the benefit of U.S. Provisional Application No. 63/478,624, filed Jan. 5, 2023, the entire disclosures of which are incorporated by reference herein.

### BACKGROUND

Optical signals are used for high-speed and secure data transmission between devices. An electro-optical device includes optical components and electronic components formed on an optical chip and an electrical chip, respectively, wherein the two chips are bonded together to provide functions of an electro-optical device. An arrangement of optical devices on the optical chip can depend on or be adjusted according to a layout of the electrical chip, and a number of optical devices is limited by the layout of the electric chip even the optical chip have space for more optical devices to be formed thereon. As the semiconductor industry has progressed into advanced technology process nodes in pursuit of smaller product scales, various approaches have been studied and an obstacle to improving density of optical devices has been encountered.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic top-view perspective of an optical device in accordance with some embodiments of the disclosure.

FIGS. 2A, 2B and 2C are schematic cross-sectional diagrams along lines A-A′, B-B′ and C-C′ in FIG. 1, respectively, in accordance with some embodiments of the disclosure.

FIGS. 3 to 13 are schematic cross-sectional diagrams at different stages of a method of manufacturing a semiconductor structure in accordance with some embodiments of the disclosure.

FIGS. 14 and 15 are schematic cross-sectional diagrams of a semiconductor structure in accordance with some embodiments of the disclosure.

FIGS. 16 to 18 are schematic cross-sectional diagrams at different stages of a method of manufacturing a semiconductor structure in accordance with some embodiments of the disclosure.

FIGS. 19 to 25 are schematic cross-sectional diagrams of a detecting structure in accordance with some embodiments of the disclosure.

FIG. 26 is a schematic cross-sectional diagram at a stage of a method of manufacturing a semiconductor structure in accordance with some embodiments of the disclosure.

FIGS. 27 to 30 are schematic cross-sectional diagrams of a detecting structure in accordance with some embodiments of the disclosure.

FIG. 31 is a schematic top-view perspective of an array of detecting structures in accordance with some embodiments of the disclosure.

FIG. 32 is a schematic top-view perspective of an array of detecting structures and coupling structures in accordance with some embodiments of the disclosure.

FIG. 33 is a flow diagram of a method of manufacturing a semiconductor structure in accordance with different embodiments of the present disclosure.

FIG. 34 is a flow diagram of a method of manufacturing a semiconductor structure in accordance with different embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides an electro-optical device and a method for manufacturing the same. The electro-optical device of the present disclosure is usable as a photodetector, and includes a photoelectric material formed between or over a P/N junction of a waveguide structure on a single chip. The present disclosure provides a novel photodetector structure and integrates waveguides and electrical circuits, which, in other approaches, are arranged on different chips, into a single chip. As a result, a product size is reduced compared to a photodetector from other approaches.

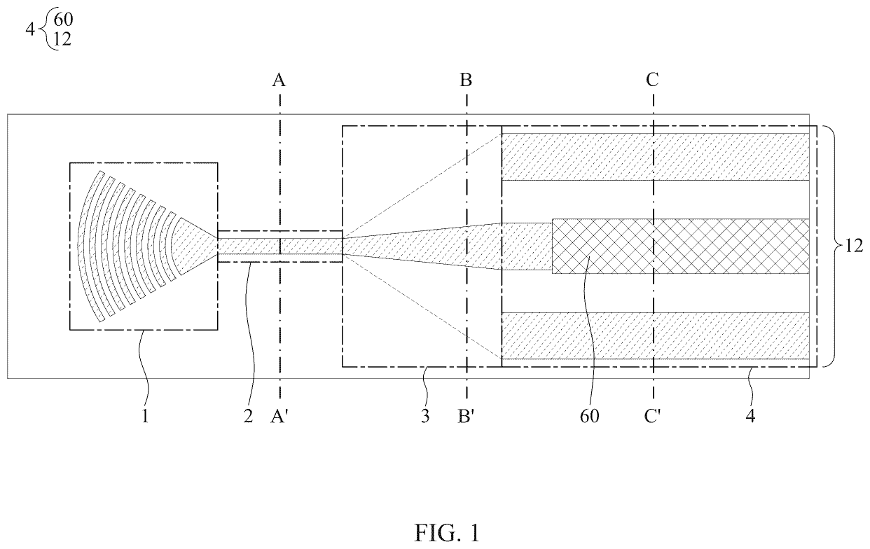

FIG. 1 is a schematic diagram of a semiconductor structure including a photodetector in accordance with some embodiments of the present disclosure. In some embodiments, the semiconductor structure includes a coupling structure 1, a guiding structure 2, a transition structure 3, and a detecting structure 4. In some embodiments, the coupling structure 1 is in a form of a periodic structure, which is configured to couple light into and out of an optical fiber. In some embodiments, the coupling structure 1 includes a grating coupler, an edge coupler, or another type of coupler. FIG. 1 shows the coupling structure 1 in a form of gratings for a purpose of illustration, but is not intended to limit the present disclosure.

The guiding structure 2 is connected to the coupling structure 1 and is configured to receive an optical signal from the coupling structure 1 and transmit a signal toward the detecting structure 4. In some embodiments, the guiding structure 2 is referred to as a strip structure since the guiding structure 2 has a strip configuration. The transition structure 3 connects the guiding structure 2 to the detecting structure 4. In some embodiments, the transition structure 3 is a transition portion between the guiding structure 2 and the detecting structure 4. In some embodiments, the detecting structure 4 has a rib configuration. In some embodiments, the detecting structure 4 is referred to as a rib structure. The detecting structure 4 is configured to convert a photon energy of the optical signal into an electrical signal. In some embodiments, the detecting structure 4 is referred to as a photodetector or a photosensor. The detecting structure 4 includes a waveguide 12 and a photoelectric material 60 overlapping a P/N junction of doping regions of the waveguide 12 (details are provided in the following paragraphs).

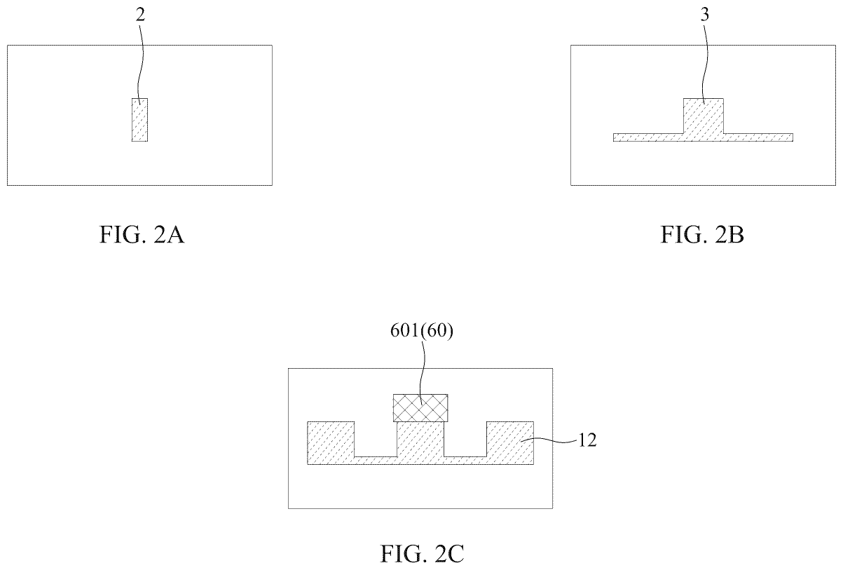

FIGS. 2A, 2B and 2C are schematic cross-sectional views along lines A-A′, B-B′ and C-C′ in FIG. 1, respectively, in accordance with some embodiments of the present disclosure. In some embodiments, the detecting structure 4 includes a waveguide 12 and a photoelectric material 601. In some embodiments, the waveguide 12 has a rib configuration. In some embodiments, the waveguide 12 includes three strips arranged in parallel. The photoelectric material 60 shown in FIG. 1 is capable of including many configurations, and the photoelectric material 601 shown in FIG. 2C is according to some embodiments of the present disclosure. In some embodiments, the photoelectric material 601 is disposed on a middle one of the three strips of the waveguide 12. The waveguide 12 and the photoelectric material 601 can be formed on or arranged within a single chip or a single wafer.

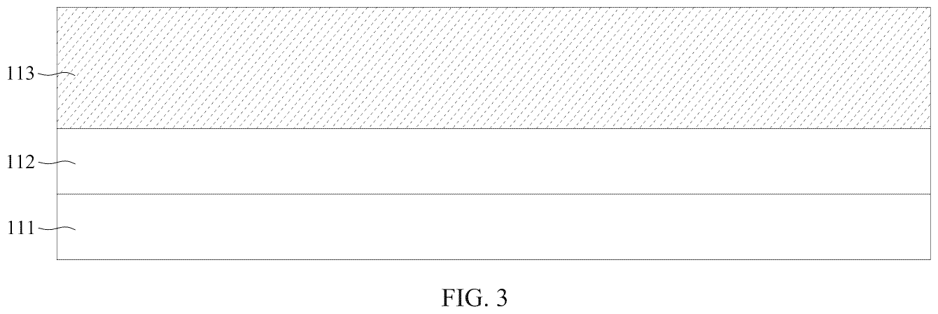

FIGS. 3 to 13 are schematic diagrams at different stages of a method for forming a detecting structure similar to the detecting structure 4 as shown in FIGS. 1 and 2C in accordance with some embodiments of the present disclosure. For a purpose of clarity and simplicity, reference numbers of elements with same or similar functions are repeated in different embodiments. However, such usage is not intended to limit the present disclosure to specific embodiments or specific elements. In addition, conditions or parameters illustrated in different embodiments can be combined or modified to form different combinations of embodiments as long as the parameters or conditions used are not in conflict.

Referring to FIG. 3, a substrate layer 111 is provided, formed or received. In some embodiments, the substrate layer 111 includes a bulk semiconductor material, such as silicon. The substrate layer 111 may include another elementary semiconductor, such as germanium; a compound semiconductor including silicon carbide, gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. An insulating layer 112 and a semiconductive material layer 113 can be sequentially formed over the substrate layer 111. In some embodiments, the semiconductive material layer 113 is formed by an epitaxial growth. In some embodiments, the insulating layer 112 includes oxide (e.g., silicon oxide). In some embodiments, the insulating layer 112 is formed by deposition. In some embodiments, a thickness of the insulating layer 112 is in a range of 2 to 5 microns (μm) for a practical purpose of electrical isolation of the semiconductive material layer 113 from the substrate layer 111 when operation. In some embodiments, the substrate layer 111, the insulating layer 112 and the semiconductive material layer 113 are collectively referred to as a semiconductor-on-insulator (SOI) substrate.

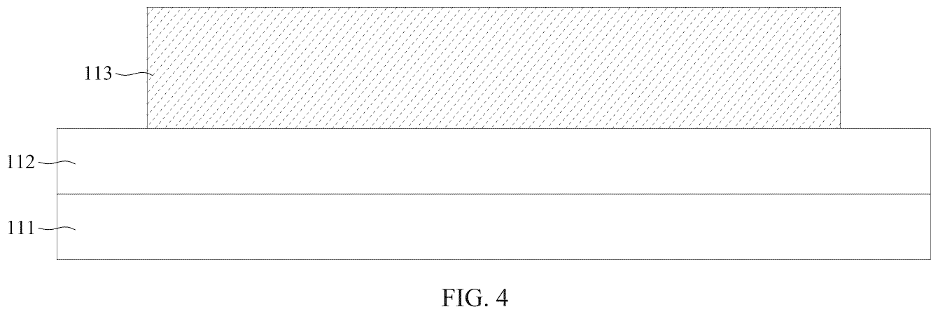

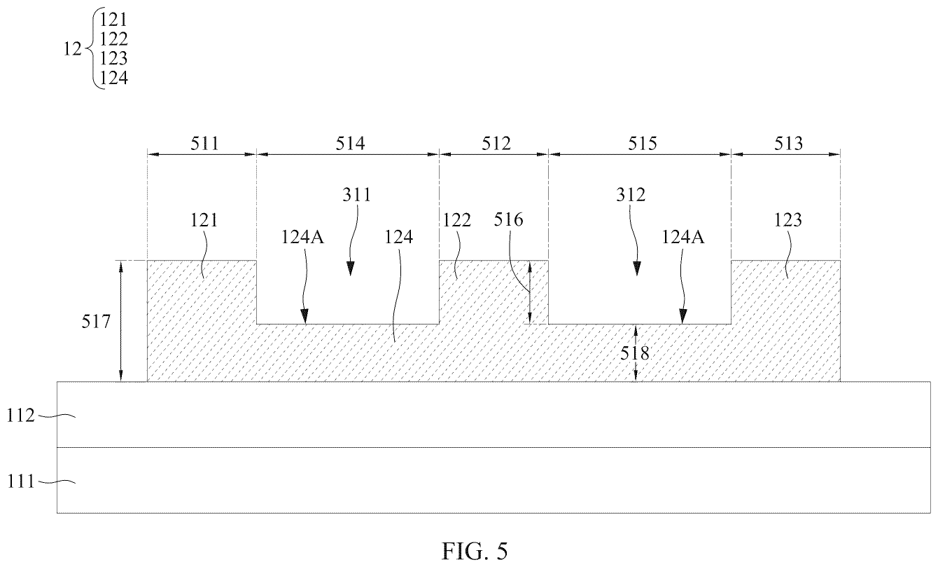

Referring to FIGS. 4 to 5, the semiconductive material layer 113 is patterned to form a waveguide 12 as shown in FIG. 5. The formation of the waveguide 12 includes multiple patterning operations. In some embodiments, portions of the semiconductive material layer 113 are removed by a first patterning operation, and portions of the insulating layer 112 are exposed as shown in FIG. 4. In some embodiments, a coverage area and a total width of the waveguide 12 are defined by the first patterning operation as shown in FIG. 4. In some embodiments, a hard mask layer (not shown) is formed covering portions of the semiconductive material layer 113 after the first patterning operation. Portions of the semiconductive material layer 113 are removed using the hard mask layer as a mask in a second patterning operation, and openings 311 and 312 are thereby formed as shown in FIG. 5. In some embodiments, the hard mask layer includes nitride (e.g., silicon nitride). In some embodiments, the hard mask layer is removed after the second patterning operation.

The waveguide 12 includes a first protrusion 121, a second protrusion 122, a third protrusion 123, and a lower member 124. In some embodiments, the lower member 124 extends along a top surface of the insulating layer 112 and across an entire width of the waveguide 12. In some embodiments, the first protrusion 121, the second protrusion 122 and the third protrusion 123 protrude from the lower member 124. In some embodiments, the second protrusion 122 is disposed between the first and third protrusions 121 and 123. In some embodiments, the protrusions 121 and 122 are separated from each other by the first opening 311; and the protrusions 122 and 123 are separated from each other by the second opening 312. In some embodiments, the first opening 311 is defined by sidewalls of the first protrusion 121 and the second protrusion 122 and a top surface 124A of the lower member 124. In some embodiments, the second opening 312 is defined by sidewalls of the second protrusion 122 and the third protrusion 123 and the top surface 124A of the lower member 124.

The first protrusion 121 may have a width 511 about 120% to 200% of a width 512 of the second protrusion 122 in order to provide a greater surficial area for a purpose of implantation and electrical connection to a contact plug. The second protrusion 122 may have the width 512 in a range of 300 to 2000 nm (nanometers) for a purpose of optical confinement. In some embodiments, loss of optical signal is significant when the width 512 is greater than 2000 nm. In some embodiments, etching accuracy is difficult to control when the width 512 is less than 300 nm. In some embodiments, a width 513 of the third protrusion 123 is substantially equal to or less than the width 511 depending on different applications. In some embodiments, a width 514 of the first opening 311 is substantially equal to a width 515 of the second opening 312. In some embodiments, the width 514 or 515 is about 100% to 200% of the width 512. The width 514 or 515 can be a factor of optical rotation (also known as polarization rotation or circular birefringence). In some embodiments, optical rotation occurs when the width 514 or 515 is less than the width 512, and loss of optical signal increases. However, a product size can be increased if the width 514 or 515 is greater than twice of the width 512. A height 517 of the waveguide 12 may be substantially equal to or less than a thickness of the semiconductive material layer 113 depending on a formation of the waveguide 12 that a thickness of the semiconductive material layer 113 can be slightly reduced or remained since the waveguide 12 is formed by performing an etching operation on the semiconductive material layer 113. In some embodiments, the height 517 is in a range of 50 to 1000 nm. It should be noted that other elements can be formed concurrently with the waveguide 12 on the semiconductive material layer 113. If a thickness of the semiconductive material layer 113 is too thin, those elements formed on the semiconductive material layer 113 are limited. However, an issue of loss of optical transition occurs when the waveguide 12 is too thick. In some embodiments, depths of the first opening 311 and the second opening 312 are substantially equal. In some embodiments, a depth 516 of the first opening 311 or the second opening 312 is about 10% to 80% of the height 517. A thickness 518 of the lower member 124 may be equal to the height 517 minus the depth 516. In other words, in some embodiments, the thickness 518 is about 20% to 90% of the height 517. The depth 516 should be less than the height 517 for a purpose of signal transmission, however, the result of an optical confinement can be affected if the lower member 124 is too thick.

It should be noted that parameters or dimensions of the first protrusion 121, the second protrusion 122, the third protrusion 123, the lower member 124, the first opening 311 and the second opening 312 are adjustable for different applications. In some embodiments, the first protrusion 121 and the third protrusion 123 function as two electrodes (or electrical terminals) of a detecting structure to be formed in subsequent processing, and the second protrusion 122 includes a P/N junction after implantations in subsequent processing.

In some embodiments, an oxide layer (not shown) is formed conformal to exposed surfaces of the waveguide 12. In some embodiments, the oxide layer is formed by an oxidation on the exposed surfaces of the waveguide 12. In some embodiments, the oxide layer is a linear layer conformal to a profile of the exposed surfaces of the waveguide 12. The exposed surfaces of the waveguide 12 are susceptible to being damaged by previous processing (e.g., the multiple patterning operations), and the formation of the oxide layer is performed to remove the damaged surfaces of the waveguide 12.

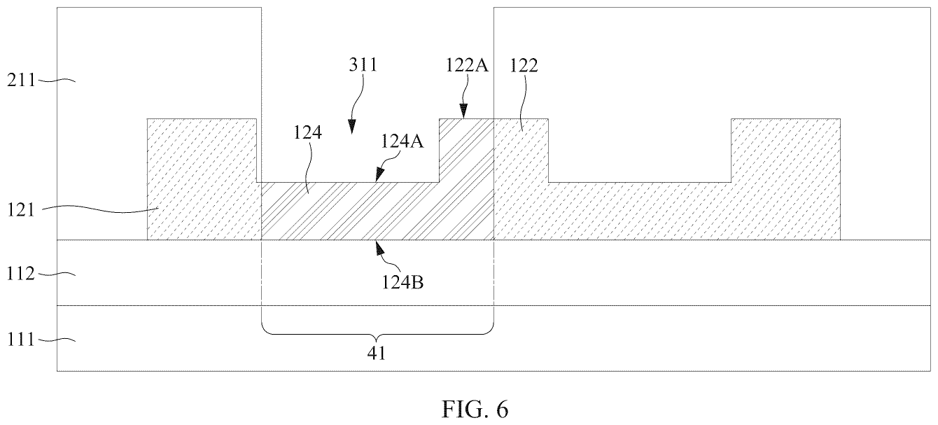

Referring to FIG. 6, a first doping region 41 is formed in a portion of the waveguide 12. In some embodiments, a photoresist layer 211 is formed covering portions of the waveguide 12 and the insulating layer 112 and exposing a portion of the waveguide 12. The photoresist layer 211 defines a position of the first doping region 41 from a top view. In some embodiments, a first implantation is performed on the exposed portion of the waveguide 12 to form the first doping region 41. In some embodiments, the first implantation includes a vertical implantation or a tilt implantation depending on different applications. In some embodiments, the first doping region 41 has an overall doping concentration in a range of 2.0E16 to 9.0E18 per cubic centimeter (cm³) for a purpose of optical confinement and signal transmission rate. If the doping concentration of the first doping region 41 is too high, the optical confinement can be affected. If the doping concentration of the first doping region 41 is too low, signal transmission of the device can be too slow. In some embodiments, the first implantation includes a first dopant having a first conductivity type (e.g., a p-type dopant).

As shown in FIG. 6, the photoresist layer 211 exposes the portion of the waveguide 12 where the first doping region 41 is to be formed, and the photoresist layer 211 covers a remainder of the waveguide 12. In some embodiments, the photoresist layer 211 at least covers the first protrusion 121, a portion of the second protrusion 122 proximal to the second opening 312, the second opening 312, and the third protrusion 123. The first doping region 41 is capable of functioning as a transition between a P/N junction and an electrode of the detecting structure (a detailed description is provided in the following paragraphs). In some embodiments, the first doping region 41 includes an entirety of the portion of the waveguide 12 exposed through the photoresist layer 211. In some embodiments, the first doping region 41 is formed in the exposed portion of the lower member 124 and extends from the top surface 124A of the lower member 124 to a bottom surface 124B of the lower member 124. In some embodiments, the first doping region 41 is formed in the exposed portion of the second protrusion 122 and extends from a top surface 122A of the second protrusion 122 to a bottom surface of the waveguide 12. In some embodiments, the photoresist layer 211 is removed after the first implantation.

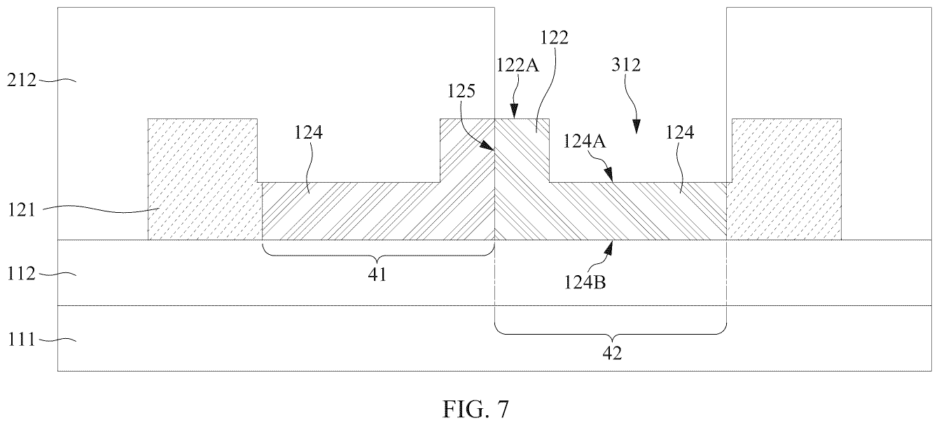

Referring to FIG. 7, operations similar to those depicted in FIG. 6 are performed to form a second doping region 42 in another portion of the waveguide 12. In some embodiments, a photoresist layer 212 is formed over the waveguide 12 and the insulating layer 112, and a second implantation is performed on an exposed portion of the waveguide 12. In some embodiments, the second implantation includes a second dopant having a second conductivity type (e.g., an n-type dopant) different from the first conductivity type. In some embodiments, the second doping region 42 has an overall doping concentration in a range of 2.0E16 to 9.0E18 per cm³ for similar reasons as the range of the doping concentration of the first doping region 41.

In some embodiments, the second doping region 42 includes an entirety of the portion of the waveguide 12 exposed through the photoresist layer 212. In some embodiments, the second doping region 42 is formed in the exposed portion of the lower member 124 and extends from the top surface 124A of the lower member 124 to the bottom surface 124B of the lower member 124. In some embodiments, the second doping region 42 is formed in the exposed portion of the second protrusion 122 and extends from the top surface 122A of the second protrusion 122 to the bottom surface of the waveguide 12. In some embodiments, the second protrusion 122 is partially exposed through the photoresist layer 212 to form a P/N junction 125 within the second protrusion 122 between the doping regions 41 and 42. In some embodiments, the photoresist layer 212 is removed after the second implantation. In some embodiments, the doping region 41 contacts the doping region 42, and the P/N junction 125 is at an interface of the doping regions 41 and 42.

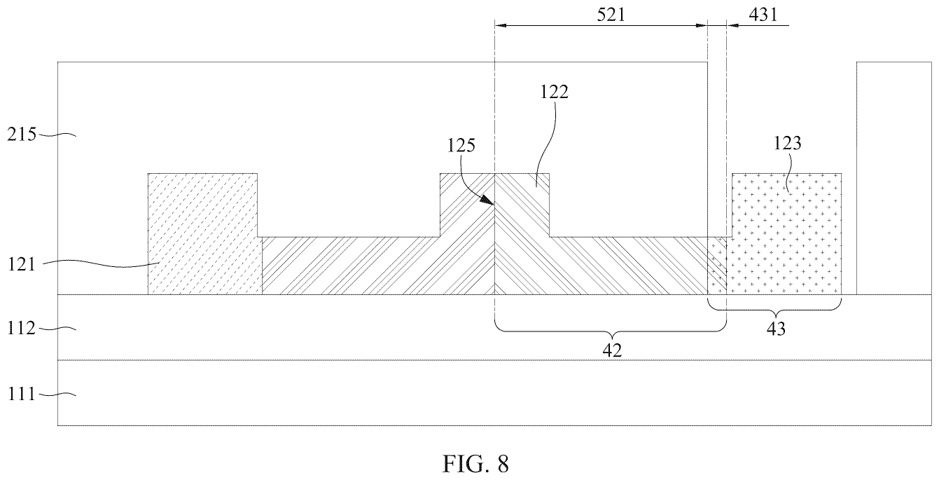

Referring to FIG. 8, operations similar to those depicted in FIG. 6 are performed to form a third doping region 43 in the third protrusion 123 adjacent to the second doping region 42. In some embodiments, a photoresist layer 215 is formed over the waveguide 12 and the insulating layer 112, and a third implantation is performed on an exposed portion of the waveguide 12. The photoresist layer 215 exposes the third protrusion 123 and covers a remainder of the waveguide 12. In some embodiment, the third implantation includes a vertical implantation or a tilt implantation. In some embodiments, the third implantation includes the second dopant having the second conductivity type (e.g., an n-type dopant). For a purpose of ensuring that the third doping region 43 contacts the second doping region 42, a portion of the lower member 124 proximal to the third protrusion 123 is exposed through the photoresist layer 215, and a sub-region 431 is formed by the third implantation. The sub-region 431 is an overlapping region of the second doping region 42 and the third doping region 43. The sub-region 431 has undergone two rounds of implantation and includes a doping concentration greater than the doping concentration of the remaining portion of the second doping region 42 or the remaining portion of the third doping region 43. It should be noted that the sub-region 431 can be formed in the lower member 124 or at a sidewall of the third protrusion 123 depending on patterns of the photoresist layers 212 and 215 shown in FIGS. 7 and 8.

In some embodiments, the third doping region 43 includes an entire height of the third protrusion 123. In some embodiments, the third doping region 43 has an overall doping concentration in a range of 1.0E18 to 9.0E20 per cm³ for a purpose of electrical connection to a contact plug to be formed. The third doping region 43 is referred to as an electrode of a detecting structure to be formed, and the third doping region 43 may have an electrical conductivity similar to an electrical conductivity of a metalloid or a metal. In some embodiments, the overall doping concentration of the third doping region 43 is greater than the overall doping concentration of the second doping region 42 by at least an order. For a purpose of illustration and ease of understanding, in the following description and figures, the sub-region 431 is defined as a part of the third doping region 43, and the second doping region 42 is re-defined as being between the P/N junction 125 and the sub-region 431 of the third doping region 43. In some embodiments, the photoresist layer 215 is removed after the third implantation.

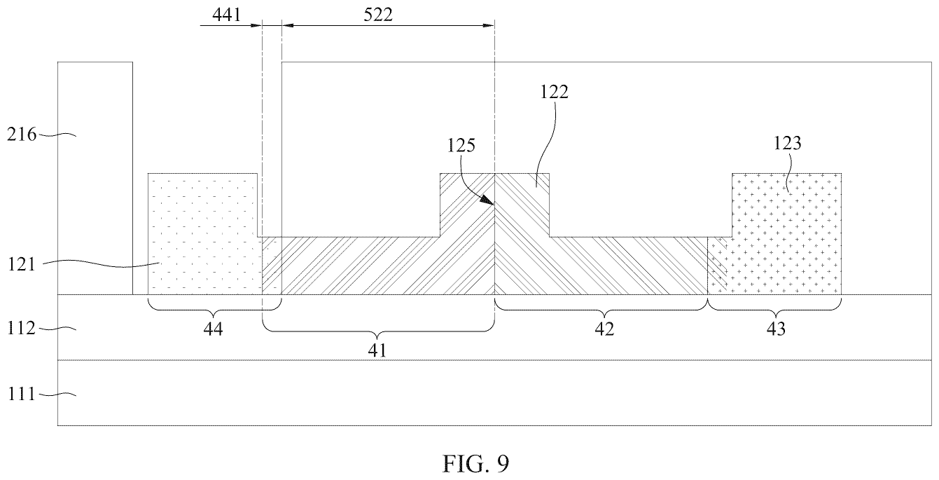

Referring to FIG. 9, operations similar to those depicted in FIG. 8 are performed to form a fourth doping region 44 in the first protrusion 121 adjacent to the first doping region 41. In some embodiments, a photoresist layer 216 is formed over the waveguide 12 and the insulating layer 112, and a fourth implantation is performed on an exposed portion of the waveguide 12. In some embodiments, the fourth implantation includes the first dopant having the first conductivity type (e.g., a p-type dopant). For a purpose of ensuring that the fourth doping region 44 contacts the first doping region 41, a portion of the lower member 124 proximal to the first protrusion 121 is exposed through the photoresist layer 216, and a sub-region 441 is formed by the fourth implantation. The sub-region 441 is an overlapping region of the first doping region 41 and the fourth doping region 44. The sub-region 441 has undergone two rounds of implantation and includes a doping concentration greater than the doping concentration of the remaining portion of the first doping region 41 or the remaining portion of the fourth doping region 44. It should be noted that the sub-region 441 can be formed in the lower member 124 or at a sidewall of the first protrusion 121 depending on patterns of the photoresist layers 211 and 216 shown in FIGS. 6 and 9.

In some embodiments, the fourth doping region 44 includes an entire height of the first protrusion 121. In some embodiments, the fourth doping region 44 has an overall doping concentration in a range of 1.0E18 to 9.0E20 per cm³ for a purpose of electrical connection to a contact plug to be formed. Similar to the reasons as the range of the overall doping concentration of the third doping region 43 as illustrated above, in some embodiments, the overall doping concentration of the first doping region 41 is greater than the overall doping concentration of the fourth doping region 44 by at least an order. For a purpose of illustration and ease of understanding, in the following description and figures, the sub-region 441 is defined as a part of the fourth doping region 44, and the first doping region 41 is re-defined as being between the P/N junction 125 and the sub-region 441 of the fourth doping region 44. In some embodiments, the photoresist layer 216 is removed after the fourth implantation. It should be noted that an operation energy, a dosage of dopants and a duration of the first, second, third or fourth implantation can be adjusted according to designed doping concentrations and a depth of a doping region to be formed, and are not limited herein.

The third doping region 43 and the fourth doping region 44 are disposed at two opposite ends of the waveguide 12 with respect to the P/N junction 125. In some embodiments, the third doping region 43 and the fourth doping region 44 are referred to as two electrodes of a photodetector to be formed in subsequent processing. In some embodiments, the first protrusion 121 and the third protrusion 123, where main distribution areas of the third doping region 43 and the fourth doping region 44 are located, are configured to receive and transmit electrical signals. In some embodiments, the first protrusion 121 and the third protrusion 123 are referred to as two electrodes of the photodetector. The P/N junction 125 is disposed in the second protrusion 122, and the optical signal from a coupling structure (e.g., the coupling structure 1 as shown in FIG. 1) is able to be confined to the second protrusion 122.

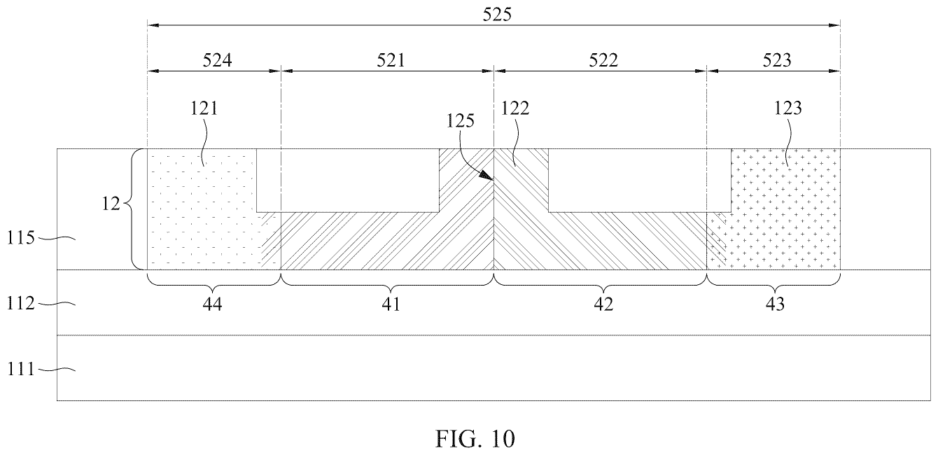

Referring to FIG. 10, a dielectric layer 115 is formed over the waveguide 12 and the insulating layer 112. In some embodiments, a deposition of a dielectric material of the dielectric layer 115 is performed. In some embodiments, the dielectric material of the dielectric layer 115 includes oxide (e.g., silicon oxide). In some embodiments, the dielectric layer 115 includes dielectric materials same as those of the insulating layer 112. In some embodiments, the dielectric material covers the waveguide 12 after the deposition, and a planarization is then performed on the dielectric material to form the dielectric layer 115 as shown in FIG. 10. In some embodiments, the planarization includes a chemical mechanical polish (CMP), a dry etching operation, a wet etching operation, or a combination thereof. In some embodiments, the planarization is performed on the dielectric material and stops upon an exposure of the waveguide 12. In some embodiments, the dielectric layer 115 has a top surface substantially aligned with a top surface of the waveguide 12. In some embodiments, the top surfaces of the first, second and third protrusions 121, 122 and 123 are exposed through the dielectric layer 115 at the top surface of the dielectric layer 115.

In some embodiments, a width 521 of the first doping region 41 is substantially equal to a width 522 of the second doping region 42. In some embodiments, the width 521 is in a range of 50% to 80% of a total of the widths 521 and 524. Loss of optical signal may increase if a distance between the junction 125 and the fourth doping region 44 is too small. In contrast, a transmission speed can be lowered down as the distance between the junction 125 and the fourth doping region 44 increases. Similarly, in some embodiments, the width 522 is in a range of 50% to 80% of a total of the widths 522 and 523. In some embodiments, a width 523 of the third doping region 43 is substantially equal to a width 524 of the fourth doping region 44. Therefore, for similar reasons as illustrated above, under a condition of a consistent width 525, in some embodiments, the width 523 or 524 is in a range of 150% to 230% of the width 512 of the second protrusion 122 shown in FIG. 5.

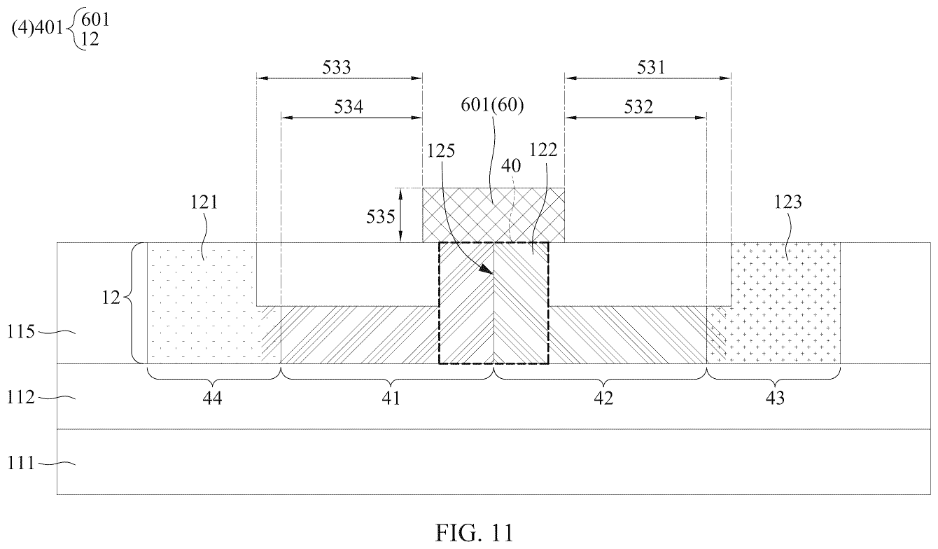

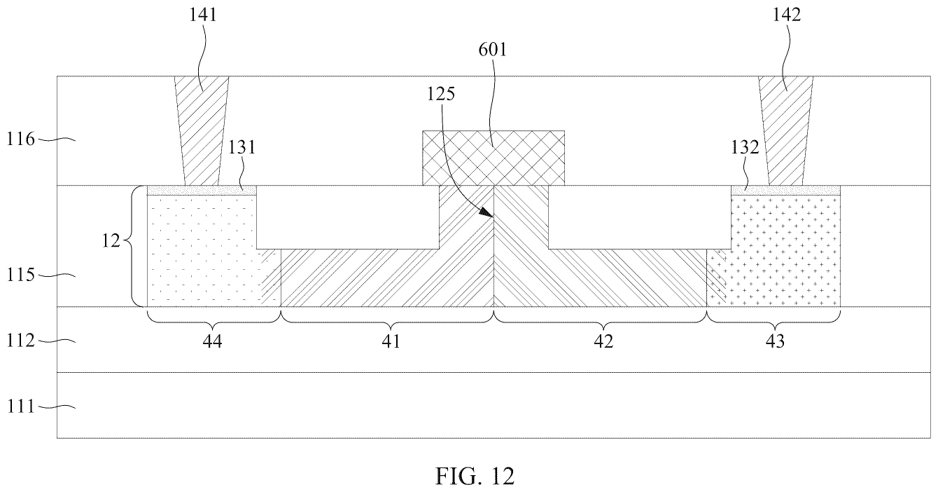

Referring to FIG. 11, a photoelectric material 601 is formed over the P/N junction 125. The photoelectric material 601 is configured to generate an electrical signal according to the optical signal received by the waveguide 12. The photoelectric material 601 can include a material selected from groups III-V on the periodic table. In some embodiments, the photoelectric material 601 includes germanium or silicon germanium. In some embodiments, the photoelectric material 601 is formed by an epitaxial growth on the second protrusion 122. In some embodiments, other operations are performed to achieve a structure as shown in FIG. 11, such as formation of a mask covering the first protrusion 121 and the third protrusion 123, or removal of epitaxial material formed on the first protrusion 121 and the third protrusion 123. In some embodiments, a distance 531 between the photoelectric material 601 and the third protrusion 123 is in a range of 35% to 99% of the width 515 shown in FIG. 5. In some embodiments, a stress between the photoelectric material 601 and a dielectric layer (e.g., 116 in FIG. 12) formed thereon increases as a surficial area of the photoelectric material 601 decreases. Therefore, the stress may be too large so that a defect of a device results with the distance 532 is less than 35% of the width 515. However, the photoelectric material 601 should not overlap or contact the third protrusion 123 to avoid short circuit. For the similar reasons, in some embodiments, a distance 533 between the photoelectric material 601 and the first protrusion 121 is in a range of 35% to 99% of the width 514 shown in FIG. 5. In some embodiments, the distance 533 is substantially equal to the distance 531.

As illustrated above, the implantation for forming the third doping region 43 shown in FIG. 8 at least covers the third protrusion 123. For a purpose of connection of different doping regions, the sub-region 431 is defined as shown in FIG. 8 and illustrated above. Therefore, for similar reasons as the ranges of the width 531 and 533 illustrated in the previous paragraphs, in some embodiments, a distance 532 between the photoelectric material 601 and the third doping region 43 is in a range of 30% to 99% of the width 515 shown in FIG. 5. In some embodiments, a distance 534 between the photoelectric material 601 and the fourth doping region 44 is in a range of 30% to 99% of the width 514 shown in FIG. 5. In some embodiments, the distance 532 is substantially equal to the distance 534. In some embodiments, a height 535 of the photoelectric material 601 is in a range of 1% to 50% of the depth 516 shown in FIG. 5. The height 535 can be a factor of a stress between the photoelectric material 601 and a dielectric layer (e.g., 116 in FIG. 12) formed thereon, and too small or too large of the height 535 can both result in defect of a device. In addition, a photoelectric conversion efficiency can be poor if the height 535 of the photoelectric material 601 is less than 1% of the depth 516. The distances 531, 532, 533 and 534 are measured along a horizontal direction, substantially parallel to an extending direction of the substrate layer 111, and the height 535 is measured along a vertical direction substantially orthogonal to the horizontal direction.

A detecting structure 401 including the waveguide 12 and the photoelectric material 601 is formed as shown in FIG. 11. It should be noted that the detecting structure 4 shown in FIG. 1 is a generic embodiment to illustrate a concept of the present disclosure, and the detecting structure 401 is usable as a specific embodiment under the concept of the present disclosure. In order to differentiate embodiments of the detecting structure 4 for a purpose of illustration, numerals used to indicate the detecting structures in FIG. 11 and the embodiments described below include 3 digits, with first digit being 4 and last two digits indicating different embodiments of the detecting structure 4. Similarly, numerals used to indicate the photoelectric material in FIG. 11 and the embodiments described below include 3 digits, with first digit being 6 and last two digits indicating different embodiments of the photoelectric material 60.

The detecting structure 401 shown in FIG. 11 is connected to the transition structure 3 shown in FIG. 1. In some embodiments, a region 40 indicated in FIG. 11 represents a region of the detecting structure 401 connected to the transition structure 3, and the region 40 is also a main region wherein the optical signal is to be confined. In some embodiments, the region 40 is referred to as a confine region 40. The photoelectric material 601 is disposed as close as possible to the P/N junction 125 or the region 40, and the optical signal is converted into an electrical signal by the photoelectric material 601. In some embodiments, a first electrical signal (or a voltage) is provided to one of the electrodes (e.g., the first protrusion 121 or the third protrusion 123) of the detecting structure 401. In some embodiments, the electrode for receiving the first electrical signal is referred to as an input terminal. In some embodiments, the electrical signal generated by the photoelectric material 601 is combined with the first electrical signal and outputted from the other electrode (e.g., the third protrusion 123 or the first protrusion 121) of the detecting structure 401. In some embodiments, the electrode for outputting the electrical signal is referred to as an output terminal.

Referring to FIG. 12, a dielectric layer 116 is formed over the detecting structure 401, and contacts 141 and 142 are formed penetrating the dielectric layer 116. The contacts 141 and 142 are for a purpose of electrical connection to the electrodes, respectively, of the detecting structure 401. In some embodiments, a silicide layer 131 and 132 is formed on each of the top surfaces of the first protrusion 121 and the third protrusion 123 for a purpose of better electrical resistance. In some embodiments, the contacts 141 and 142 are aligned with and electrically connected to the first protrusion 121 and the third protrusion 123, respectively. In some embodiments, the contacts 141 and 142 are formed after the formation of the dielectric layer 116. In some embodiments, portions of the dielectric layer 116 over the first protrusion 121 and the third protrusion 123 are removed, and the contacts 141 and 142 are formed therewithin. In some embodiments, the contacts 141 and 142 are formed by a deposition or a plating operation. In some embodiments, each of the contacts 141 and 142 includes one or more conductive materials. For example, in some embodiments, the conductive material includes at least one of tungsten (W), aluminum (Al), copper (Cu), silver (Ag), gold (Au), titanium (Ti), tantalum (Ta), ruthenium (Ru), titanium-nitride (TiN), tantalum-nitride (TaN), ruthenium nitride (RuN), tungsten nitride (WN), and alloys thereof. In some embodiments, the dielectric layer 116 includes a dielectric material that is same as or different from that of the dielectric layer 115 depending on applications.

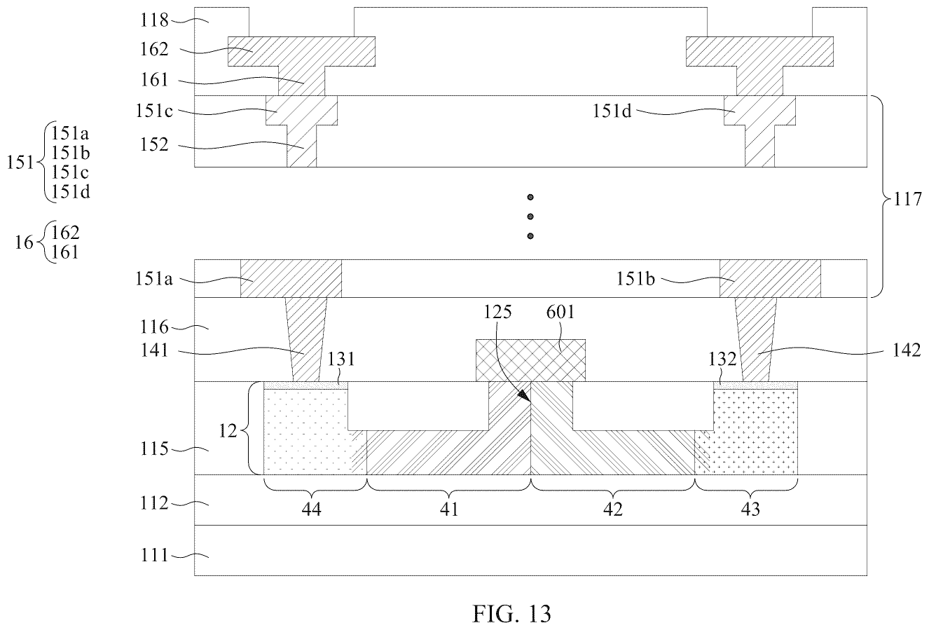

Referring to FIG. 13, an interconnect structure including a dielectric layer 117, a plurality of conductive lines 151, and a plurality of conductive vias 152 is formed over the dielectric layer 116. For the sake of brevity, details on forming an interconnect structure are not provided here. In some embodiments, the dielectric layer 117 includes multiple sub-layers of dielectric materials. Each of the conductive lines 151 and each of the conductive vias 152 are surrounded by the dielectric layer 117. In some embodiments, different layers of the conductive lines 151 are electrically connected by the conductive vias 152. In some embodiments, the contacts 141 and 142 connect to a bottommost layer of the conductive lines 151 (e.g., conductive lines 151a and 151b are disposed in a first layer of the conductive lines 151 of the interconnect structure above the dielectric layer 116). In some embodiments, the bottommost layer of the conductive lines 151 is referred to as a first metal line layer (M1) of the interconnect structure. In some embodiments, the contacts 141 and 142 electrically connect to a topmost layer of the conductive lines 151 (e.g., conductive lines 151c and 151d are disposed in a topmost layer of the interconnect structure). In some embodiments, the contact 141 is electrically connected to the conductive line 151c, and the contact 142 is electrically connected to the conductive line 151d. The conductive lines 151 and the conductive vias 152 may have same conductive material(s). The conductive material may be selected from the list of conductive materials of the contact 141 or 142 as described above. In some embodiments, the conductive lines 151 or the conductive vias 152 include conductive materials different from those of the contact 141 or 142.

A passivation layer 118 and a connector structure 16 surrounded by the passivation layer 118 is formed over the interconnect structure. In some embodiments, the passivation layer 118 includes nitride, polyimide, or a combination thereof. In some embodiments, the passivation layer 118 is formed by a deposition operation. In some embodiments, the deposition operation includes a chemical vapor deposition (CVD), a physical vapor deposition (PVD), an atomic layer deposition (ALD), a low-pressure chemical vapor deposition (LPCVD), a plasma-enhanced CVD (PECVD), or a combination thereof. In some embodiments, the passivation layer 118 is a multi-layer structure. The connector structure 16 is formed by one or more depositions of a conductive material. In some embodiments, portions of the passivation layer 118 are removed prior to the deposition of the conductive material. In some embodiments, the conductive material of the connector structure 16 includes aluminum (Al), copper (Cu), tungsten (W), titanium (Ti), tantalum (Ta), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru), titanium silicon nitride (TiSiN), other suitable materials, or a combination thereof. In some embodiments, the connector structure 16 includes a via portion 161 and a pad portion 162. The connector structure 16 is for a purpose of electrical connection to the electrodes of the detecting structure 401. In some embodiments, the connector structure 16 is electrically connected to the conductive lines 151 in a topmost layer of the interconnect structure. In some embodiments, the pad portion 162 of the connector structure 16 is exposed through the passivation layer 118 for electrical connection to another chip, an electric device, an electrical component, or a power source.

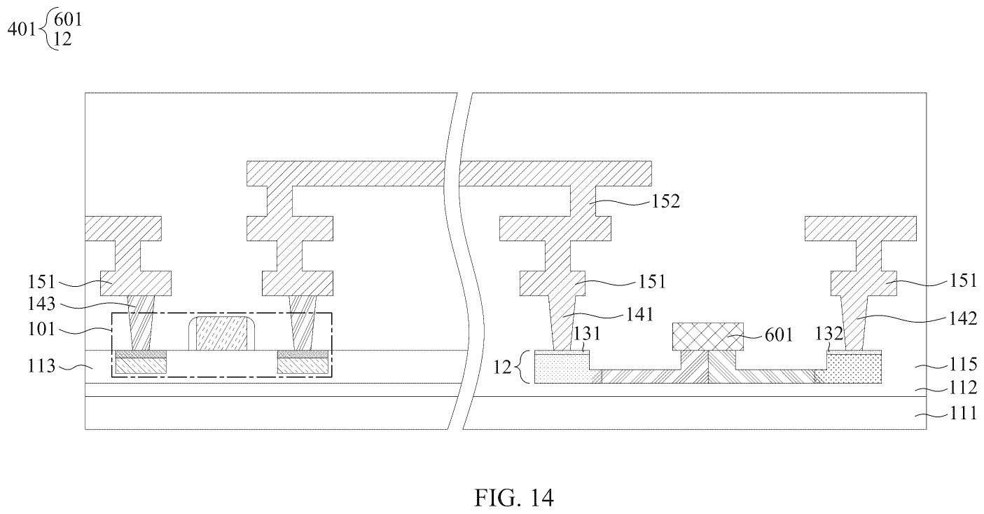

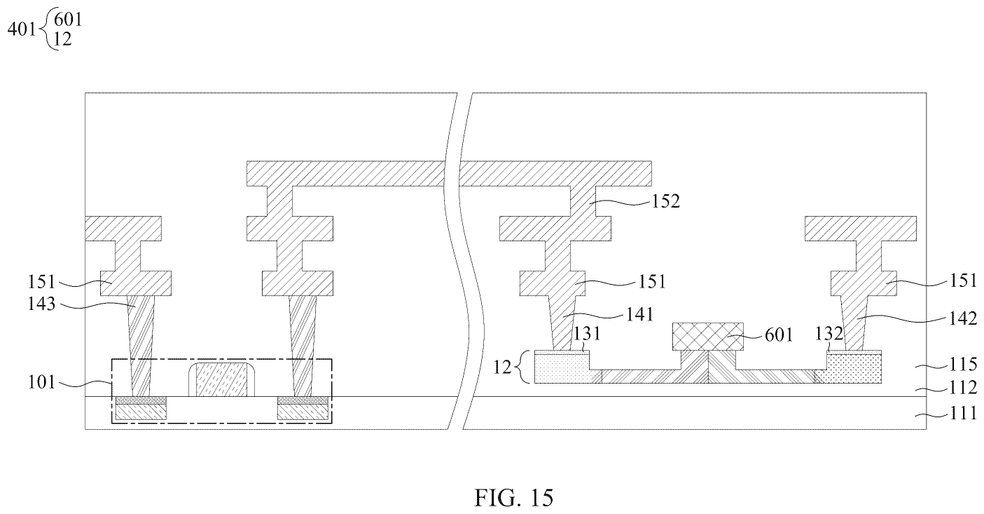

In some embodiments, the detecting structure 401 is formed by front-end-of-line (FEOL) processing and formed concurrently with an electrical circuit, e.g., transistors of a logic device, on a single chip or a single wafer. FIGS. 14 and 15 are schematic diagrams of semiconductor structures in accordance with some embodiments of the present disclosure, wherein FIG. 14 shows a transistor 101 and a detecting structure 401 formed on an SOI substrate, and FIG. 15 shows a transistor 101 and a detecting structure 401 formed on a bulk substrate. The transistor 101 is disposed on the substrate at a level same as a level of the waveguide 12 or the detecting structure 401. The transistor 101 and the detecting structure 401 may be disposed in different regions of the substrate. It should be noted that, for a purpose of simplicity, only one transistor 101 is depicted in each of FIGS. 14 and 15, but the disclosure is not limited thereto. In addition, in some embodiments, the transistor 101 is a planar transistor, a multi-gate transistor, a gate-all-around field-effect transistor (GAAFET), a fin field-effect transistor (FinFET), a vertical transistor, a plurality thereof, or a combination thereof.

In some embodiments, the transistor 101 is formed on the semiconductive material layer 113, and one or more dielectric layers (e.g., 115 and/or 116) are formed on the semiconductive material layer 113 covering the transistors 101 as shown in FIG. 14. In some embodiments, the transistor 101 is formed on the substrate layer 111, and one or more dielectric layers (e.g., 115 and/or 116) are formed on the substrate layer 111 covering the transistors 101 as shown in FIG. 15. In some embodiments, the insulating layer 112 includes an interlayer dielectric layer. In some embodiments, contacts 143 are formed together with the contacts 141 and 142 to electrically connect to source/drain (S/D) regions and a gate structure of the transistor 101. In some embodiments, the contacts 141, 142 and 143 are formed concurrently by middle-end-of-line (MEOL) processing. In some embodiments, the contacts 143 include tungsten. In some embodiments, the contacts 143 include copper. A material of the contacts 143 depends on different applications or device generations. An interconnect structure formed over the transistor 101 and the detecting structure 401 are able to provide electrical connections between the detecting structure 401 and the transistor 101. In some embodiments, the detecting structure 401 electrically connects to the transistor 101 through the interconnect structure.

In some instances, a photodetector includes an optical device and an electrical device formed on different chips, and the optical device and the electrical device are bonded together to form the photodetector. As described above, a layout and a density of the optical device are limited by a layout of the electrical device. The present disclosure provides a photodetector including an optical portion and an electrical portion formed on a single chip or a single wafer. The formation of the optical portion and the electrical portion of the photodetector are integrated into the FEOL. A chip area is reduced in comparison with other approaches, and a cost of a manufacturing process is also reduced in comparison with other approaches.

The detecting structure 401 of the embodiments shown in FIGS. 11 to 15 includes the photoelectric material 601 disposed over the P/N junction 125 and the second protrusion 122. However, the position of the photoelectric material 601 is an exemplary embodiment for a purpose of illustration of function and manufacturing process. The photoelectric material 601 is a type or a configuration of the photoelectric material 60 in accordance with some embodiments of the present disclosure. Different configurations of photoelectric materials 60 (e.g., 602, 603, 604, 605, 606, 607, 608, 609, 610, 611, 612 and 613) are provided according to different embodiments in the following paragraphs.

In the following description, different detecting structures with functions or performances similar to those of the detecting structure 4 shown in FIGS. 11 to 15 are provided within a same concept of the present disclosure. For a purpose of simplicity, only differences between the embodiments are illustrated in the following description, and similar or same functions, properties, positions and formations of elements are omitted.

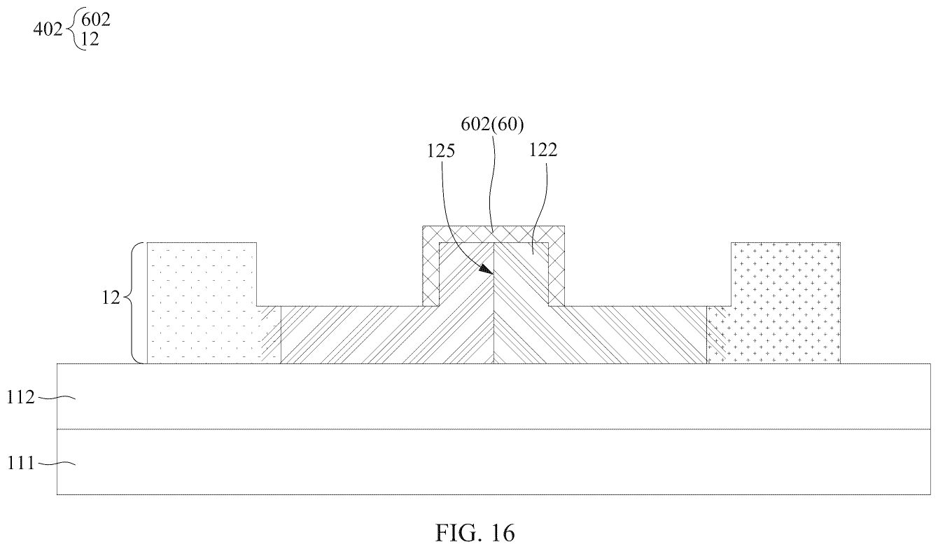

Referring to FIG. 16, a photoelectric material 602 is formed surrounding the second protrusion 122 after the operations depicted in FIG. 9 in accordance with some embodiments of the present disclosure. In some embodiments, after removal of the photoresist layer 216 and prior to formation of the dielectric layer 115, an epitaxial growth is performed. In some embodiments, an entirety of the second protrusion 122 is exposed during the epitaxial growth. An increase of an area of overlap of the photoelectric material 602 and the doping regions 41 and 42 (e.g., compared to the photoelectric material 601) is found to result in an improved electro-optical performance. In some embodiments, the first protrusion 121, the third protrusion 123 and the lower member 124 are covered by a hard layer, a dielectric layer or a mask layer. In some embodiments, the photoelectric material 602 is formed only on the second protrusion 122. In some embodiments, the photoelectric material 602 surrounds the P/N junction 125. In some embodiments, the photoelectric material 602 is a crystalline structure. A detecting structure 402 including the photoelectric material 602 is thereby formed.

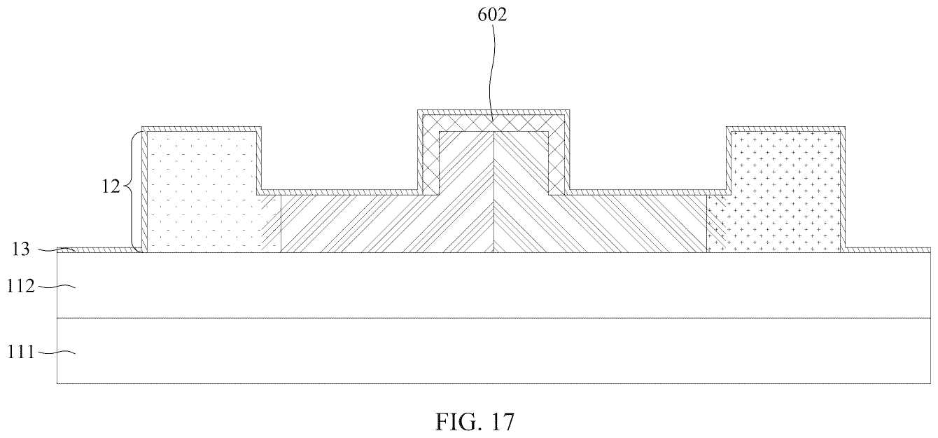

Referring to FIG. 17, a high-k layer 13 is optionally formed over the detecting structure 402. In some embodiments, the high-k layer 13 provides better confinement of the optical signal in the detecting structure 402 compared to other types of dielectric material (e.g., a low-k material). In some embodiments, the high-k layer 13 is conformal to the detecting structure 402. In some embodiments, the high-k layer 13 is in direct contact with the detecting structure 402.

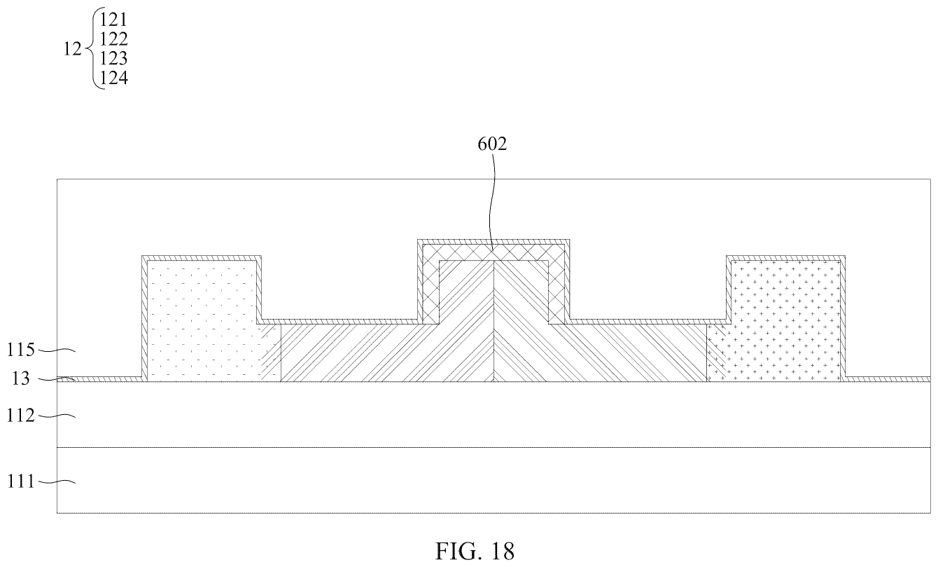

Referring to FIG. 18, a dielectric layer 115 is formed over the high-k layer 13. In some embodiments, the dielectric layer 115 covers an entirety of the detecting structure 402. In some embodiments, the dielectric layer 115 is formed by a deposition followed by a planarization. In some embodiments, the dielectric layer 115 covers an entirety of the high-k layer 13 as shown in FIG. 18. In some embodiments, the dielectric layer 115 exposes a top surface of the high-k layer 13 over the photoelectric material 602 (not shown). The operations depicted in FIGS. 12 to 13 are then able to be performed on the intermediate structure shown in FIG. 18, and portions of the high-k layer 13 covering top surfaces of the first protrusion 121 and the third protrusion 123 are removed prior to the formation of the contacts 141 and 142 shown in FIG. 12 for a purpose of electrical connection.

It should be noted that the high-k layer 13 are optionally applied in other embodiments of the present disclosure; for a purpose of simplicity, the high-k layer 13 is omitted in the following embodiments.

The photoelectric materials 601 and 602 are formed by epitaxial growth as described above. A photoelectric material 60 in other embodiments are formed by other operations, such as an implantation, and the photoelectric material 60 comprise a doping region formed within a patterned semiconductive material layer 113. In the following description, detecting structures with different locations of the photoelectric material 60 with respect to the waveguide 12 are provided. For a purpose of simplicity, the following embodiments focus on the detecting structures without showing other elements, such as the substrate layer 111, the insulating layer 112, the dielectric layers 115 and 116, the interconnect structure, the passivation layer 118, and so forth. However, such omissions are not intended to limit the present disclosure.

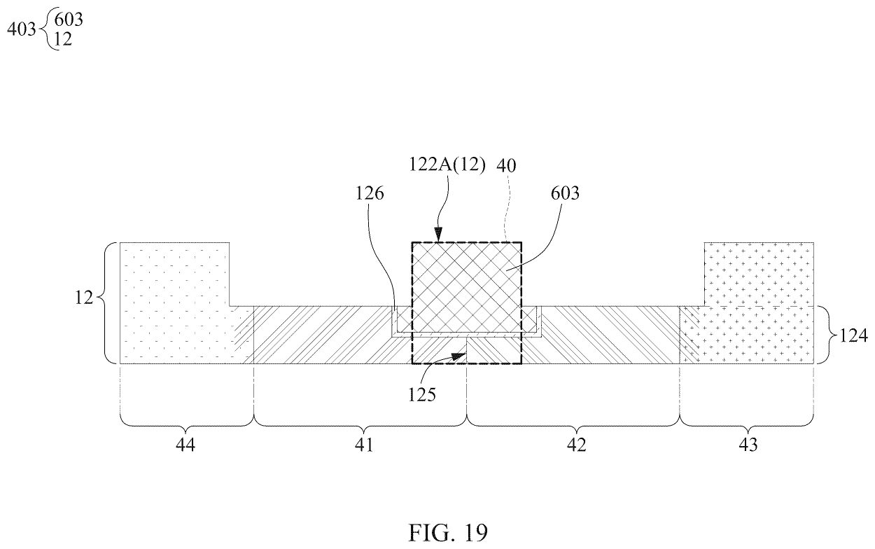

Referring to FIG. 19, in some embodiments of the present disclosure, a photoelectric material 603 is doped or implanted into a region of a waveguide 12, and a detecting structure 403 is thereby formed. In some embodiments, the region of the implanted photoelectric material 603 is referred to as a photoelectric region 603. For ease of illustration and understanding, the photoelectric material is referred to as a photoelectric region in those embodiments having a photoelectric material 60 formed by an implantation. The first, second, third and fourth implantations as illustrated above are adjusted to form doping regions 41, 42, 43 and 44 as shown in FIG. 19. As illustrated above, an energy, a dosage and/or a power of an implantation can be adjusted to control a depth, a concentration, and a coverage area of a doping region to be formed. Detailed descriptions of the forming of the doping regions 41, 42, 43 and 44 as shown in FIG. 19 are omitted herein for the sake of brevity.

In addition to the first, second, third and fourth implantations as described above, the method further includes a fifth implantation to form the photoelectric region 603 as shown in FIG. 19. An order of the first, second, third, fourth and fifth implantations is not limited herein and depends on locations of the doping regions 41, 42, 43 and 44 and the photoelectric region 603. In some embodiments, the fifth implantation includes introduction of silicon germanium. In some embodiments, the photoelectric region 603 covers an entirety of the second protrusion 122. In some embodiments, the photoelectric region 603 extends to portions of the lower member 124 proximal to the second protrusion 122.

Similar to positions of the photoelectric materials 601 and 602 as described above, the photoelectric region 603 is disposed proximal to a P/N junction 125. In some embodiments, the photoelectric region 603 is disposed vertically over the P/N junction 125. However, different from the epitaxial structure of the photoelectric material 601 or 602, the photoelectric region 603 is separated from the doping regions 41, 42, 43 and 44. In some embodiments, the photoelectric region 603 is separated from the doping regions 41 and 42 by an intrinsic region 126 of the waveguide 12. In some embodiments, the intrinsic region 126 is a doping-free region of the waveguide 12. In some embodiments, the intrinsic region 126 is a region of the semiconductive material layer 113 (as shown in FIGS. 4 and 5) free of dopants implanted therein. In some embodiments, the intrinsic region 126 includes a material same as that of the semiconductive material layer 113. In some embodiments, the photoelectric region 603 at least partially overlaps a confine region 40 of optical confinement. In some embodiments, the photoelectric region 603 extends from a top surface 122A of the second protrusion 122 to the lower member 124 and below a top surface of the lower member 124. In some embodiments, the photoelectric region 603 extends laterally beyond a coverage of the confine region 40.

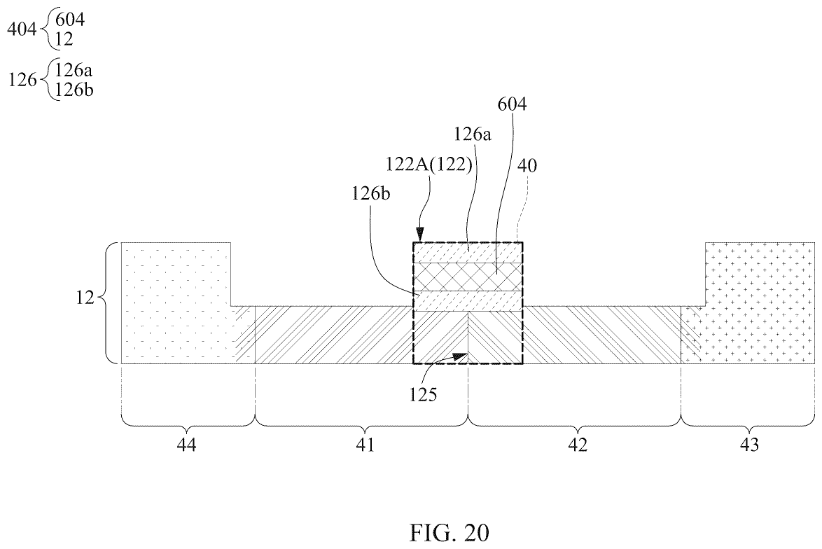

Referring to FIG. 20, in some embodiments of the present disclosure, a photoelectric region 604 is formed, wherein the photoelectric region 604 is similar to the photoelectric region 603 but has a coverage area less than that of the photoelectric region 603. In some embodiments, the photoelectric region 604 is disposed in the second protrusion 122. In some embodiments, an entirety of the photoelectric region 604 is within the second protrusion 122. In some embodiments, the photoelectric region 604 is separated from a top surface 122A of the second protrusion 122, e.g., by a first intrinsic region 126a. In some embodiments, the photoelectric region 604 is separated from the doping regions 41 and 42 by a second intrinsic region 126b.

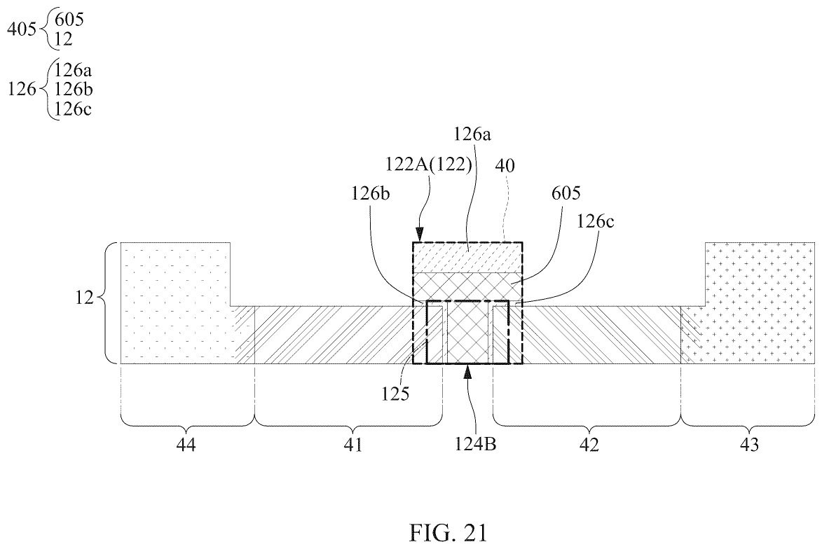

Referring to FIG. 21, in some embodiments of the present disclosure, a photoelectric region 605 is formed, wherein the photoelectric region 605 is similar to the photoelectric region 604 but has an additional portion extending toward a bottom surface 124B of a lower member 124, thereby forming a detecting structure 405. In some embodiments, the photoelectric region 605 is disposed at a P/N junction 125. In some embodiments, a doping region 41 is separated from a doping region 42; however, the P/N junction 125 is still generated when a bias or a voltage is provided to the detecting structure 405. The P/N junction 125 is indicated by a dashed rectangle labeled 125 in FIG. 21. In some embodiments, the photoelectric region 605 is located over the P/N junction 125 and extends downward between the doping regions 41 and 42. In some embodiments, the photoelectric region 605 forms a T-shape in a cross-sectional view as shown in FIG. 21. In some embodiments, the photoelectric region 605 contacts the bottom surface 124B of the lower member 124. In some embodiments, the photoelectric region 605 is separated from a top surface 122A of the second protrusion 122 by a first intrinsic region 126a, separated from the doping region 41 by a second intrinsic region 126b, and separated from the doping region 42 by a third intrinsic region 126c.

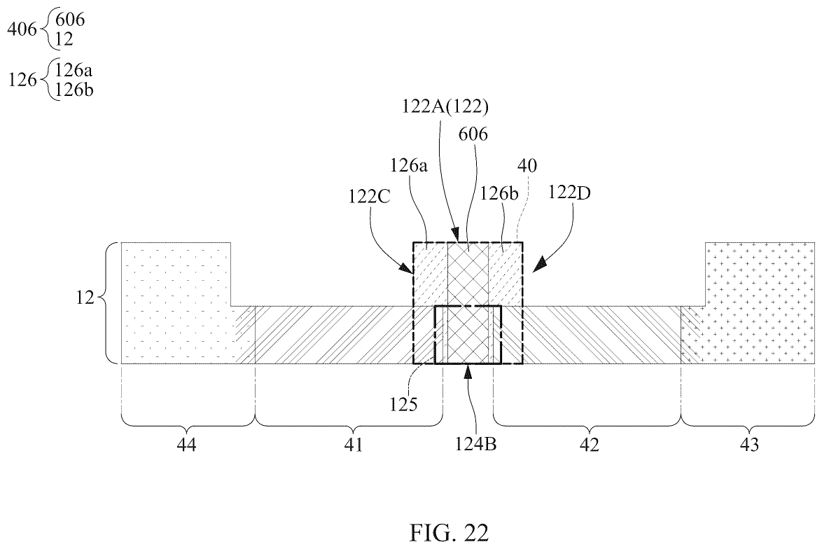

Referring to FIG. 22, in some embodiments of the present disclosure, a photoelectric region 606 is formed, wherein the photoelectric region 606 is similar to the photoelectric region 605 but extends from a top surface 122A of the second protrusion 122 to a bottom surface 124B of a lower member 124, thereby forming a detecting structure 406. In some embodiments, the photoelectric region 606 forms an I-shape in a cross-sectional view as shown in FIG. 22. In some embodiments, the photoelectric region 606 extends between doping regions 41 and 42 and above a P/N junction 125. In some embodiments, the photoelectric region 606 contacts the top surface 122A of the second protrusion 122 and the bottom surface 124B of the lower member 124. In some embodiments, the photoelectric region 606 is separated from sidewalls of the second protrusion 122. In some embodiments, the photoelectric region 606 is separated from a first sidewall 122C and the doping region 41 by a first intrinsic region 126a, wherein the first sidewall 122C faces a first protrusion 121 and is proximal to the doping region 41. In some embodiments, the photoelectric region 606 is separated from a second sidewall 122D and the doping region 42 by a second intrinsic region 126b, wherein the second sidewall 122D is opposite to the first sidewall 122C and proximal to the doping region 42.

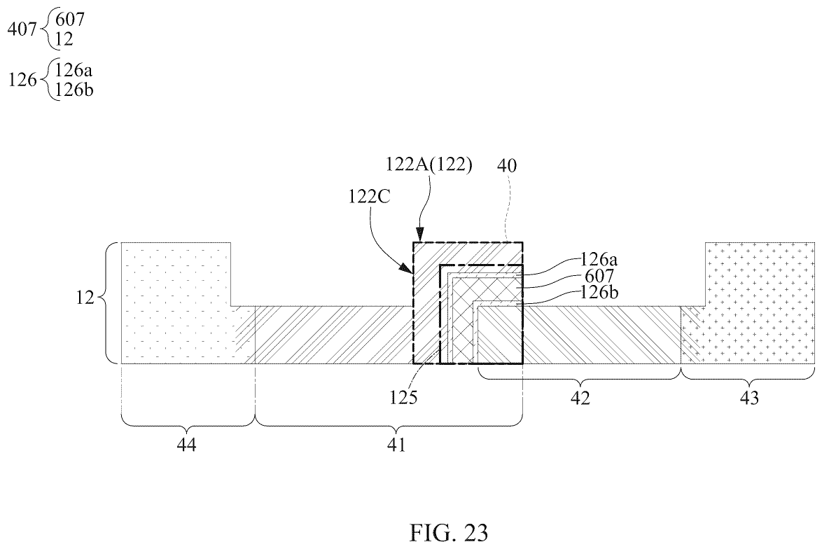

Referring to FIG. 23, in some embodiments of the present disclosure, a photoelectric region 607 is formed, wherein the photoelectric region 607 is similar to the photoelectric region 605 but without a lateral extension over a doping region 41, thereby forming a detecting structure 407. In some embodiments, a doping region 41 overlaps a doping region 42 from a top-view perspective. In some embodiments, the doping region 41 extends along a sidewall 122C and a top surface 122A of the second protrusion 122. In some embodiments, the doping region 42 is separated from the doping region 41 and extends from a doping region 43 to beyond the second protrusion 122. In some embodiments, the photoelectric region 607 is disposed between the doping regions 41 and 42. In some embodiments, a first intrinsic region 126a extends along or lines a boundary or periphery of the doping region 41 at a P/N junction 125, and the photoelectric region 607 is separated from the doping region 41 by the first intrinsic region 126a. In some embodiments, a second intrinsic region 126b extends along or lines a boundary or periphery of the doping region 42 at the P/N junction 125, and the photoelectric region 607 is separated from the doping region 42 by the second intrinsic region 126b.

Similar to the illustration of the photoelectric material 602, an increase of an area of overlap of the photoelectric region 607 and the doping regions 41 and 42 has been found to improve electro-optical performance over that of the photoelectric region 606. It has further been found that an increase of an area of overlap of a photoelectric region and a p-type doping region can have a greater influence on the electro-optical performance compared to an increase of an area of overlap of a photoelectric region and an n-type doping region. In some embodiments as shown in FIG. 23, a boundary or periphery of the doping region 41 overlapping the photoelectric region 607 is substantially larger than a boundary or periphery of the doping region 42 overlapping the photoelectric region 607, wherein the doping region 41 has a p-type conductivity, and the doping region 42 has an n-type conductivity.

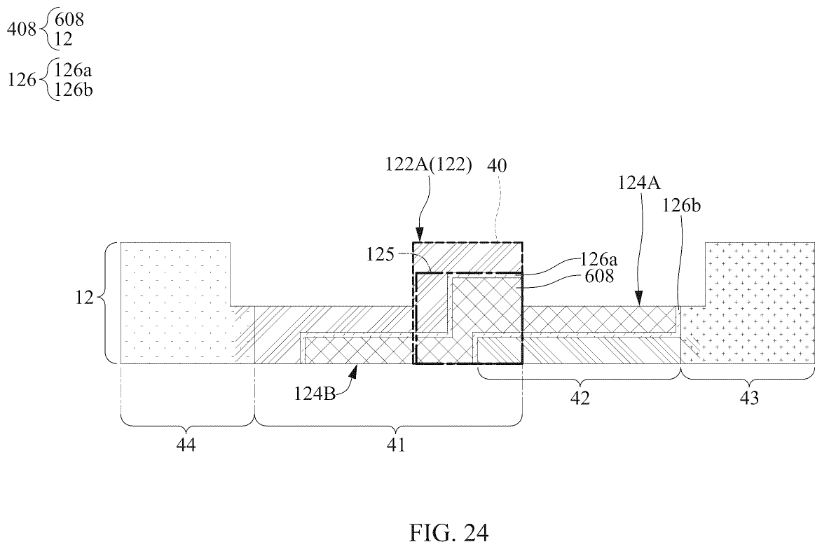

Referring to FIG. 24, in some embodiments of the present disclosure, a photoelectric region 608 is formed, wherein the photoelectric region 608 is similar to the photoelectric region 607 but has additional extensions toward doping regions 41 and 42 respectively, thereby forming a detecting structure 408. In some embodiments, the photoelectric region 608 is disposed between the doping regions 41 and 42 at a P/N junction 125 and extends along a top surface 124A of the lower member 124 toward a doping region 43. In some embodiments, the photoelectric region 608 is disposed above the doping region 41. In some embodiments, the photoelectric region 608 extends from the P/N junction 125 along a bottom surface 124B of the lower member 124 toward the doping region 41. In some embodiments, the photoelectric region 608 is disposed below the doping region 41. In some embodiments, a first intrinsic region 126a extends along or lines a boundary or periphery of the doping region 41 facing downward toward the photoelectric region 608, such that the photoelectric region 608 is separated from the doping region 41 by the first intrinsic region 126a. In some embodiments, a second intrinsic region 126b extends along or lines a boundary or periphery of the doping region 42 facing upward toward the photoelectric region 608, such that the photoelectric region 608 is separated from the doping region 42 by the second intrinsic region 126b.

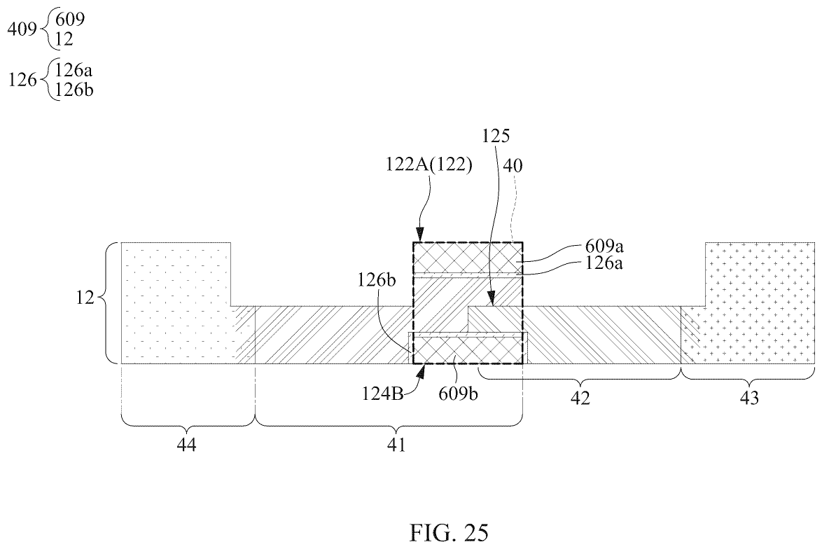

Referring to FIG. 25, in some embodiments of the present disclosure, a photoelectric region 609 is formed, wherein the photoelectric region 609 includes multiple sub-regions surrounding a P/N junction 125, thereby forming a detecting structure 409. In some embodiments, the photoelectric region 609 includes a first sub-region 609a and a second sub-region 609b separately disposed above and below the P/N junction 125. In some embodiments, the first sub-region 609a is disposed at a top surface 122A and the second sub-region 609b is disposed at a bottom surface 124B of a lower member 124. In some embodiments, a portion of the doping region 41 in the second protrusion 122 is disposed above a portion of the doping region 42 in the second protrusion 122 for a purpose of increasing a periphery of the doping region 41 at the P/N junction. In some embodiments, the first sub-region 609a is separated from the doping regions 41 and 42 by a first intrinsic region 126a extending laterally within the second protrusion 122. In some embodiments, the second sub-region 609b is separated from the doping regions 41 and 42 by a second intrinsic region 126b surrounding the second sub-region 609b in the lower member 124 below the P/N junction 125.

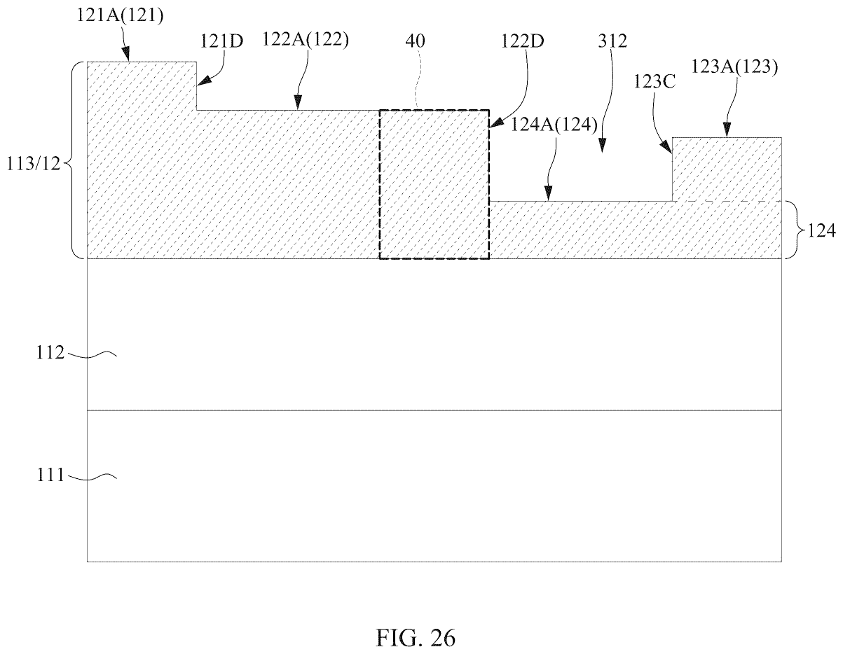

Referring to FIG. 26, the operations as depicted in FIG. 5 are adjusted to form a waveguide 12 from the semiconductive material layer 113 as shown in FIG. 26. In some embodiments, different patterning operations are performed to provide the waveguide 12. Details of the formation of the waveguide 12 are omitted herein for the sake of brevity. In some embodiments, a top surface 121A of a first protrusion 121 is above a top surface 122A of a second protrusion 122. In some embodiments, a top surface 123A of a third protrusion 123 is substantially below or aligned with the top surface 122A of the second protrusion 122. In some embodiments, the top surface 122A of the second protrusion 122 is connected to a sidewall 121D of the first protrusion 121 facing toward the second protrusion 122. In some embodiments, a lower member 124 extends between the first protrusion 121 and the third protrusion 123. In some embodiments, an opening 312 is defined between the second protrusion 122 and the third protrusion 123. In some embodiments, a sidewall 122D of the second protrusion 122 and a sidewall 123C of the third protrusion 123 face each other and define the opening 312. In some embodiments, a top surface 124A of the lower member 124 is exposed by the opening 312 between the second protrusion 122 and the third protrusion 123. In some embodiments, no opening is defined between the first protrusion 121 and the second protrusion 122. In some embodiments, the first protrusion 121, the second protrusion 122 and a portion of the lower member 124 at the opening 312 together define a stair configuration.

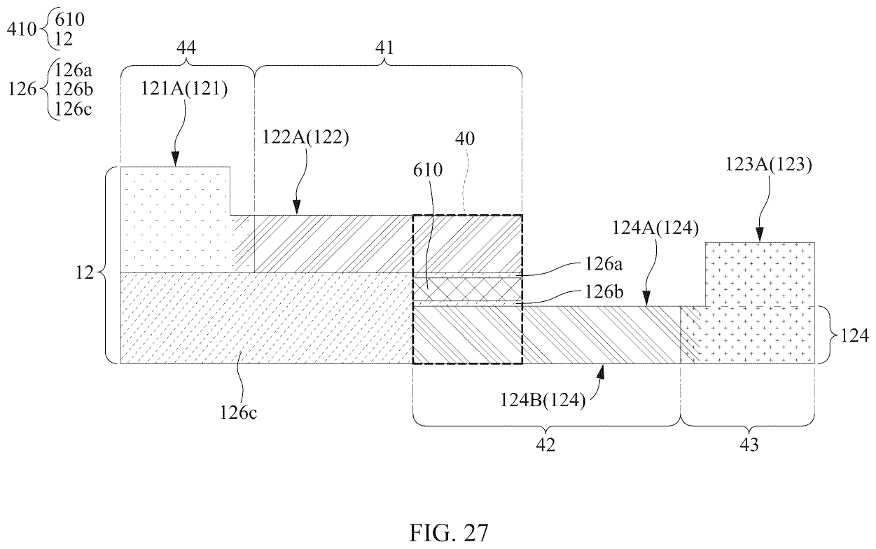

Referring to FIG. 27, in some embodiments of the present disclosure, multiple implantations are performed on a waveguide 12 similar to the waveguide shown in FIG. 26 to form a detecting structure 410. In some embodiments, a doping region 41 extends from a top surface 122A of a second protrusion 122 toward a lower member 124 and stops above the lower member 124. In some embodiments, a doping region 44 extends from a top surface 121A of a first protrusion 121 toward the lower member 124 and stops above the lower member 124. In some embodiments, a bottom of the doping region 44 is substantially aligned with or at a level substantially same as a bottom of the doping region 41. In some embodiments, a doping region 42 extends from a top surface 124A of the lower member 124 toward a bottom surface 124B of the lower member 124. In some embodiments, the doping regions 41 and 42 are overlapping from a top view. In some embodiments, the doping regions 41 and 42 are overlapping in a confine region 40 of the waveguide 12. In some embodiments, a portion of the doping region 42 is under the second protrusion 122 and overlapped by a portion of the doping region 41. In some embodiments, a top of the portion of the doping region 42 overlapped by the portion of the doping region 41 is at a level of the top surface 124A of the lower member 124. In some embodiments, the doping region 41 and the doping region 42 are separated by a default distance for a photoelectric region 610 to be subsequently disposed therebetween. In some embodiments, the photoelectric region 610 is disposed within the second protrusion 122. In some embodiments, the photoelectric region 610 is separated from the doping region 41 by a first intrinsic region 126a and separated from the doping region 42 by a second intrinsic region 126b. In some embodiments, the photoelectric region 610 is substantially parallel to the doping region 41 or the doping region 42. In some embodiments, the photoelectric region 610 extends laterally across the confine region 40. The waveguide 12 may include a third intrinsic region 126c, wherein the first intrinsic region 126a and the second intrinsic region 126b are for purpose of separation of the photoelectric region 610 and the doping regions 41 and 42, and a presence of the third intrinsic region 126c is because it is not for the doping region 41 or the doping region 42 to extend all the way to the bottom surface 124B of the lower member 124. In some embodiments, the third intrinsic region 126c is a dopant-free region to provide a better optical confinement in the confine region 40.

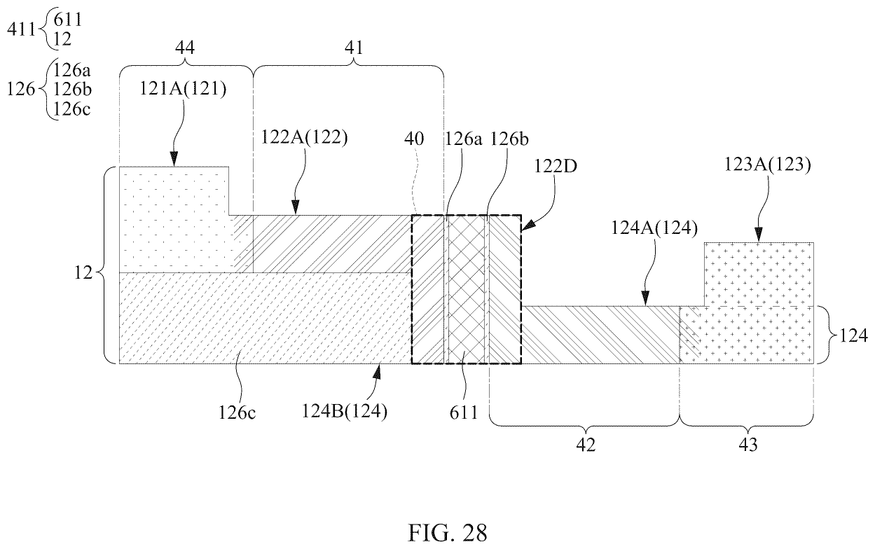

Referring to FIG. 28, in some embodiments of the present disclosure, a detecting structure 411 is formed, wherein the detecting structure 411 is similar to the detecting structure 410 but has a photoelectric region 611 extending along a vertical direction instead of a lateral direction. Doping regions 43 and 44 and portions of doping regions 41 and 42 outside a confine region 40 are similar to those shown in FIG. 27, and repeated description is omitted herein. For ease of understanding, the following description focuses on an arrangement of different doping regions 41, 611 and 42 in the confine region 40. In some embodiments, the doping region 41 in the confine region 40 extends from a top surface 122A of the second protrusion 122 to a bottom surface 124B of the lower member 124. In some embodiments, the photoelectric region 611 is laterally adjacent to the doping region 41 and extends from the top surface 122A of the second protrusion 122 to the bottom surface 124B of the lower member 124. In some embodiments, the doping region 42 in the confine region 40 extends from the top surface 122A of the second protrusion 122 to the bottom surface 124B of the lower member 124, and from a sidewall 122D of the second protrusion 122 toward the photoelectric region 611. In some embodiments, a first intrinsic region 126a between the photoelectric region 611 and the doping region 41 extends vertically from the top surface 122A of the second protrusion 122 to the bottom surface 124B of the lower member 124. In some embodiments, a second intrinsic region 126b between the photoelectric region 611 and the doping region 42 extends vertically from the top surface 122A of the second protrusion 122 to the bottom surface 124B of the lower member 124.

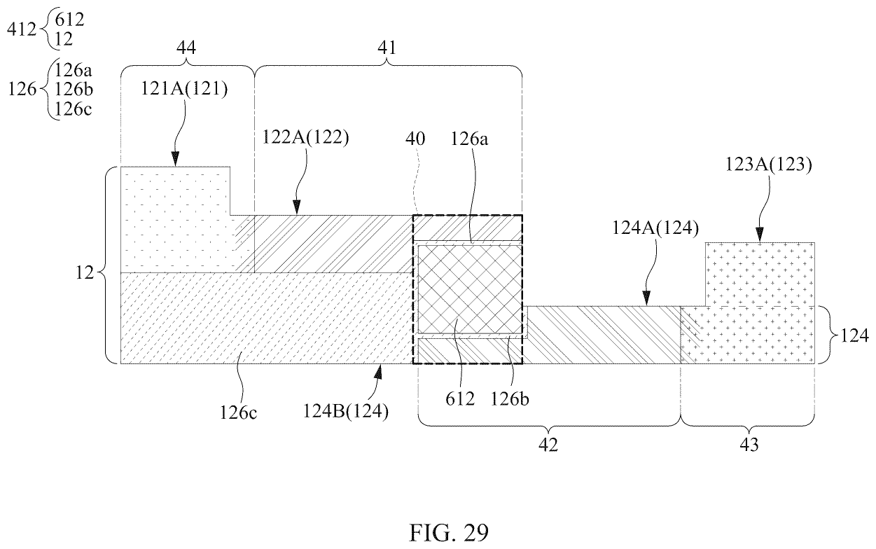

Referring to FIG. 29, in some embodiments of the present disclosure, a photoelectric region 612 is formed, wherein the photoelectric region 612 is similar to the photoelectric region 610, but a height of the photoelectric region 612 is greater than that of the photoelectric region 610, and a detecting structure 412 is thereby formed. For ease of description and understanding, only differences from the photoelectric region 610 are provided in the following description of the photoelectric region 612. In contrast to the embodiments illustrated in FIG. 27, the photoelectric region 612 extends upward toward a doping region 41 and downward toward a doping region 42 for a purpose of increasing an area of overlap of the photoelectric region 612 and the doping region 41 and an area of overlap of the photoelectric region 612 and the doping region 42. In some embodiments, in contrast to the embodiments shown in FIG. 27, a portion of a lower boundary of the doping region 41 in a confine region 40 is pushed upward due to the expansion of the photoelectric region 612. Similarly, in some embodiments, in contrast to the embodiments shown in FIG. 27, a portion of an upper boundary of the doping region 42 in the confine region 40 is pushed downward due to the expansion of the photoelectric region 612.

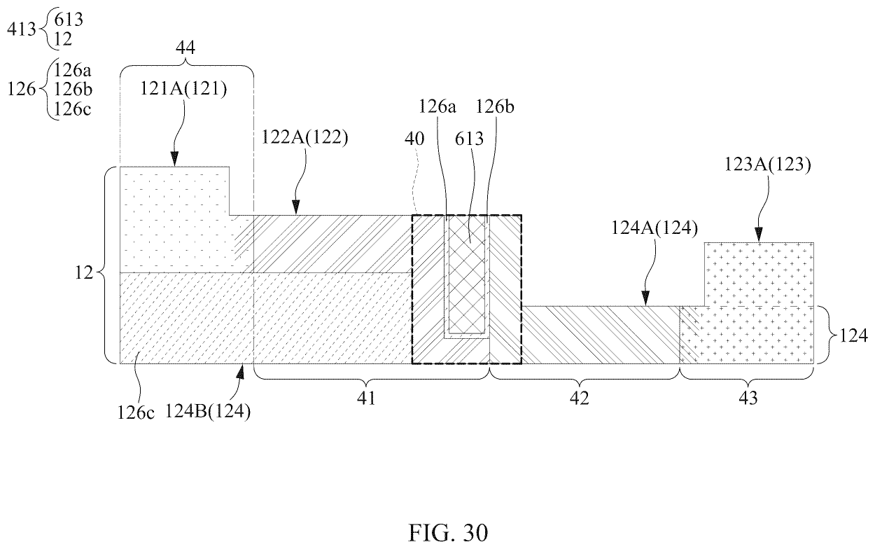

Referring to FIG. 30, in some embodiments of the present disclosure, a photoelectric region 613 is formed, wherein the photoelectric region 613 is similar to the photoelectric region 611 but has a bottom surrounded by a doping region 41, thereby forming a detecting structure 413. In some embodiments, the photoelectric region 613 extends from a top surface 122A of a second protrusion 122 and stops above a bottom surface 124B of a lower member 124. In some embodiments, the doping region 41 extends along the bottom surface 124B of the lower member 124 and toward the doping region 42. In some embodiments, the doping region 41 contacts the doping region 42 in the lower member 124 below the photoelectric region 613. In some embodiments, a first intrinsic region 126a between the photoelectric region 613 and the doping region 41 extends vertically from the top surface 122A of the second protrusion 122 and lines a bottom of the photoelectric region 613. In some embodiments, a second intrinsic region 126b between the photoelectric region 613 and the doping region 42 extends vertically from the top surface 122A of the second protrusion 122 and connects to the first intrinsic region 126a.

In some embodiments, the detecting structure 4 of the present disclosure is formed on a single chip. In order to improve a density of the chip, an arrangement of a plurality of the detecting structures 4 is provided.

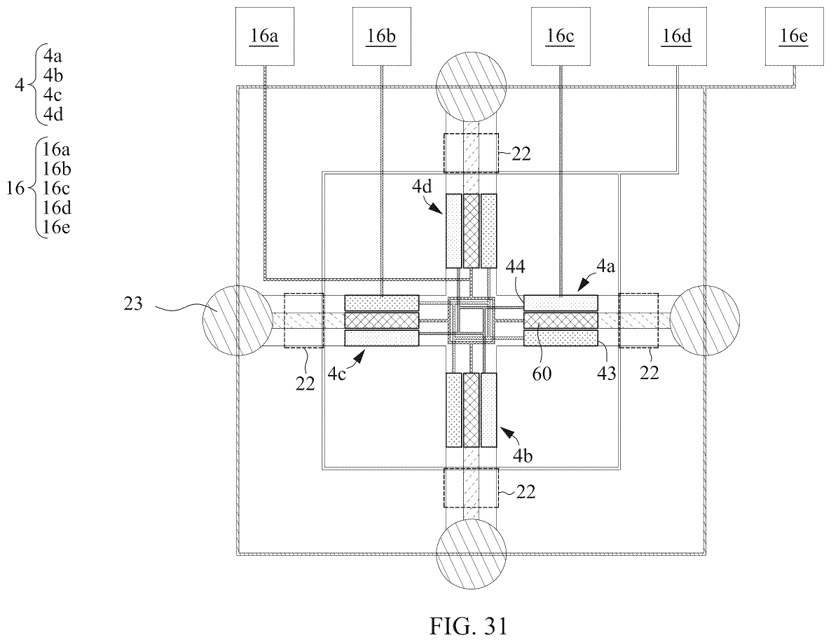

FIG. 31 is a schematic top-view perspective of a plurality of detecting structures 4 in accordance with some embodiments of the present disclosure. In some embodiments, the plurality of detecting structures 4 is arranged in a circular manner to form a round shape from the top-view perspective. In some embodiments, the round shape is a circle, and the plurality of detecting structures 4 are uniformly distributed around a center of the circle from the top-view perspective. In some embodiments, orientations of the detecting structures 4 are different from the top-view perspective. In some embodiments, the detecting structures 4 are directed toward the center of the circle. In some embodiments, each of the detecting structures 4 includes a photoelectric material and a waveguide, as in other embodiments as illustrated above. In some embodiments, each of the waveguides of the detecting structures has a rib configuration, and strips of the waveguides of the detecting structures 4 are all connected, as shown in FIG. 31. In some embodiments, the strips of different detecting structures 4 extend toward a center of the round shape and are connected at the center of the round shape. In some embodiments, the plurality of detecting structures 4 includes four photodetectors 4a, 4b, 4c and 4d. However, a number of the detecting structures 4 is for a purpose of illustration only, and is not intended to limit the present disclosure. In some embodiments, the photodetectors 4a, 4b, 4c and 4d together define a shape of a cross from the top-view perspective. In some embodiments, FIG. 31 is a top-view perspective of an electro-optical chip. In some embodiments, the detecting structures 4 together define an electro-optical array.

Other electrical devices, such as attenuators, amplifiers and modulators, are able to be integrated with the detecting structures 4 as shown in FIG. 31. In some embodiments, attenuators 22 are connected to each of extensions of the detecting structures 4. In some embodiments, the extensions are formed concurrently with the waveguide 12 by the one or more patterning operations as depicted in FIGS. 4 and 5. In some embodiments, the extensions are formed from the semiconductive material layer 113 as shown in FIG. 3. The attenuator 22 are structurally similar to a waveguide, and a bias provided on the attenuators 22 are adjusted corresponding to a desired power level of an optical signal. In some embodiments, modulators 23 are connected to each of the extensions of the detecting structures 4. The modulator 23 is structurally similar to a waveguide. One of ordinary skill in the art would understand how to provide the modulators 23.

In some embodiments, photoelectric materials 60 of different detecting structures 4 are electrically connected through an interconnect structure disposed thereabove. For a purpose of simplicity, the interconnect structure is not shown in FIG. 31 and is similar to the interconnect structure as shown in FIG. 13. In some embodiments, the photoelectric materials 60 of different detecting structures 4 are electrically connected to a single connector structure 16 (e.g., the connector structure 16a) through the interconnect structure. In some embodiments, doping regions 43 of different detecting structures 4 are electrically connected through the interconnect structure, wherein the doping regions 44 of different detecting structures 4 have a second conductivity different from the first conductivity. In some embodiments, the doping regions 43 of different detecting structures 4 are electrically connected to a single connector structure 16 (e.g., the connector structure 16b) through the interconnect structure. In some embodiments, doping regions 44 of different detecting structures 4 are electrically connected through the interconnect structure disposed thereabove, wherein the doping regions 44 of different detecting structures 4 have a first conductivity. In some embodiments, the doping regions 44 of different detecting structures 4 are electrically connected to a single connector structure 16 (e.g., the connector structure 16c) through the interconnect structure. In some embodiments, all or multiple of the attenuators 22 are electrically connected to a single connector structure 16 (e.g., the connector structure 16d) through the interconnect structure. In some embodiments, all or multiple of the modulators 23 are electrically connected to a single connector structure 16 (e.g., the connector structure 16e) through the interconnect structure.

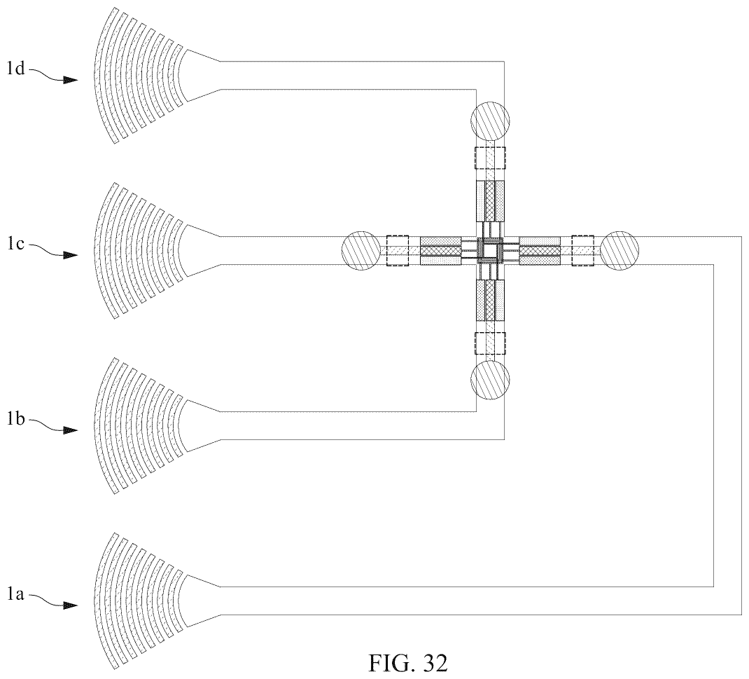

FIG. 32 is a schematic diagram showing connections between the detecting structures 4 as shown in FIG. 31 and corresponding coupling structures 1. In some embodiments, the coupling structures 1 include couplers 1a, 1b, 1c and 1d respectively connected to the photodetectors 4a, 4b, 4c and 4d for transmission of optical signals. In some embodiments, the coupling structures 1 are disposed at a same side of the electro-optical array. However, the present disclosure is not limited thereto. Positions of the coupling structures 1 with respect to the electro-optical array are adjustable according to different applications.

To conclude the processes of different embodiments as described above, a method 700 and a method 800 within a same concept of the present disclosure are provided.

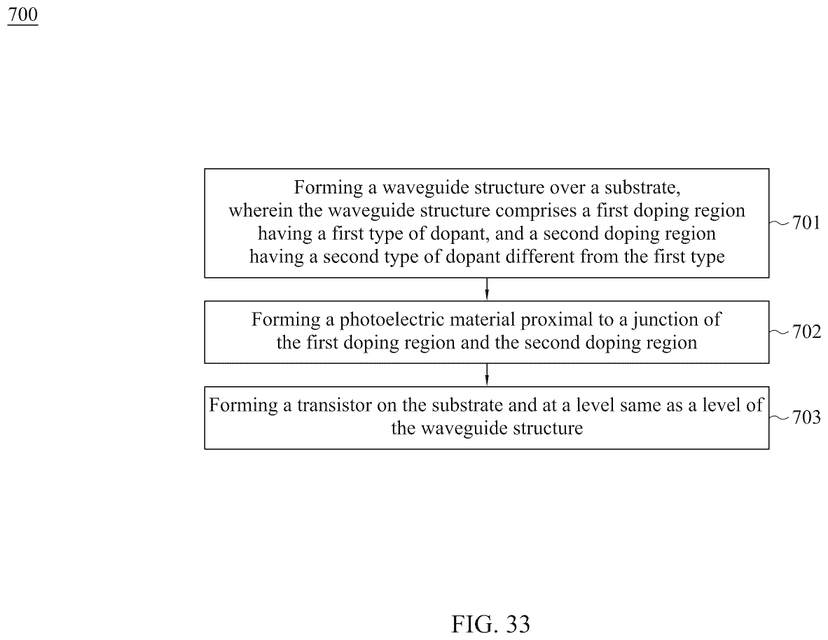

FIG. 33 is a flow diagram of the method 700 for manufacturing a semiconductor structure in accordance with some embodiments of the present disclosure. The method 700 includes a number of operations (701, 702 and 703), and the description and illustration are not deemed as a limitation to the sequence of the operations. In the operation 701, a waveguide structure is formed over a substrate, wherein the waveguide structure comprises a first doping region having a first type of dopant and a second doping region having a second type of dopant different from the first type. In the operation 702, a photoelectric material is formed proximal to a junction of the first doping region and the second doping region. In the operation 703, a transistor is formed on the substrate and at a level same as a level of the waveguide structure.

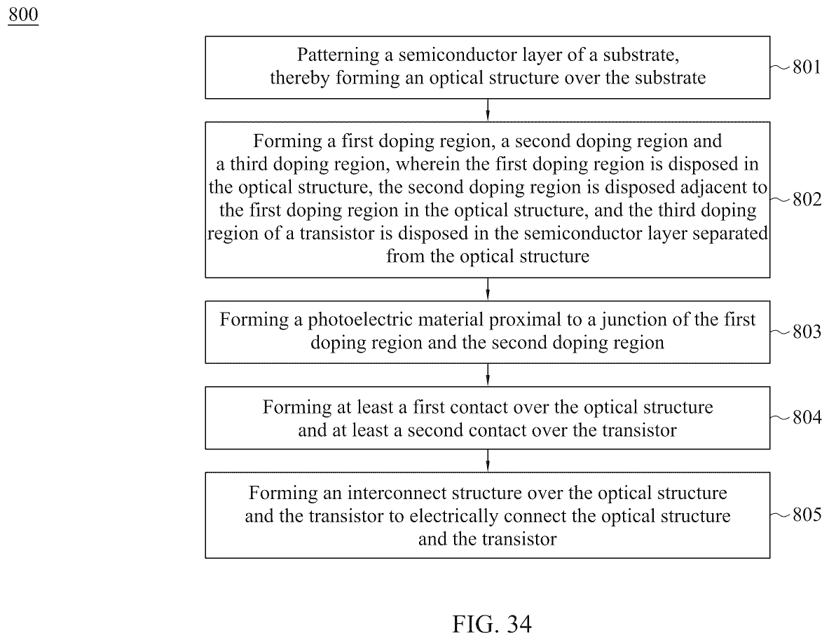

FIG. 34 is a flow diagram of the method 800 for manufacturing a semiconductor structure in accordance with some embodiments of the present disclosure. The method 800 includes a number of operations (801, 802, 803, 804 and 805), and the description and illustration are not deemed as a limitation to the sequence of the operations. In the operation 801, a semiconductor layer of a substrate is patterned, and thereby an optical structure is formed over the substrate. In the operation 802, a first doping region, a second doping region and a third doping region are formed, wherein the first doping region is disposed in the optical structure, the second doping region is disposed adjacent to the first doping region in the optical structure, and the third doping region is included in a transistor and disposed in the semiconductor layer separated from the optical structure. In the operation 803, a photoelectric material is formed over and proximal to a junction of the first doping region and the second doping region. In the operation 804, at least a first contact is formed over the optical structure and at least a second contact is formed over the transistor. In the operation 805, an interconnect structure is formed over the optical structure and the transistor to electrically connect the optical structure and the transistor.

For a purpose of illustration, the embodiment shown in FIG. 0.14 is used as an exemplary embodiment to illustrate the method 800. Referring to the operation 801, a semiconductor layer (e.g., 113 shown in FIG. 14) is patterned to form an optical structure (e.g., 112). Referring to the operation 802, a source/drain region of the transistor 101 can be formed concurrently with the doping region 43 or 44 by the implantation shown in FIG. 8 or FIG. 9 depending on a type of conductivity of the transistor 101. In some embodiments, the operation 802 can also include formation of an LDD (lightly doped drain) region (not shown in FIG. 14) concurrently with the doping region 41 or 42 by the implantation shown in FIG. 6 or 7. The first doping region and the second doping region in the operation 802 include different types of dopants. The first doping region in the operation 802 can be the doping region 41 or 44 or a combination of the doping regions 41 and 44. The second doping region in the operation 802 can be the doping region 42 or 43 or a combination of the doping regions 42 and 43. In some embodiments, one or more doping regions (e.g., source/drain regions and/or LDD regions) of the transistor 101 is formed prior to the operation 803. In some embodiments, the operation 804 is performed after the operation 803. In some embodiments, a silicide layer is formed between the source/drain regions and the contacts 143. In some embodiments, the silicide layer is formed concurrently with the silicide layer 131 and 132 as labeled in FIG. 12. In some embodiments, the silicide layer of the optical structure 12 (e.g., 131 and 132) and the silicide layer of the transistor 101 are formed after the operation 803 and prior to the operation 804. Referring to the operation 804, the contacts 143 are formed concurrently with or together with the contacts 141 and 142. Therefore, the detecting structure 4 of the present disclosure can be formed concurrently with and at a same elevation as the transistor 101.

It should be noted that, in the operation 802, the doping regions 41, 42, 43 and 44 can be formed together with or concurrently with one or more doping regions or well regions of the transistor 101, and the above illustration is not intended to limit the present disclosure. In other embodiments, one of the doping regions 41, 42, 43, 44 can be formed together with a body well region, a deep well region, an active region, or other doped region of the transistor or other areas of the semiconductive material layer 113 other than the detecting structure 4. Details of the process can be adjusted depending on different applications.

It should be noted that the operations of the method 700 and/or the method 800 are able to be rearranged or otherwise modified within the scope of the various aspects. In some embodiments, additional processes are provided before, during, and after the method 700 and/or the method 800, and some other processes are only briefly described herein. Thus, other implementations are possible within the scope of the various aspects described herein.

In accordance with some embodiments of the disclosure, a semiconductor structure is provided. The semiconductor structure includes a waveguide structure, a photoelectric material, and a transistor. The waveguide structure is disposed on a substrate and includes a first doping region having a first type of dopant and a second doping region having a second type of dopant different from the first type. The photoelectric material is disposed proximal to a junction of the first doping region and the second doping region. The transistor is disposed on the substrate at a level same as a level of the waveguide structure.

In accordance with some embodiments of the disclosure, a semiconductor structure is provided. The semiconductor structure includes a first photodetector and a second photodetector, wherein the first photodetector is configured to detect a first optical signal and the second photodetector is configured to detect a second optical signal. The first photodetector includes a first waveguide, extending along a first direction from a top-view perspective and comprising a first input terminal and a first output terminal; and a first photoelectric layer, disposed between the first input terminal and the first output terminal. The second photodetector includes a second waveguide, extending along a second direction different from the first direction from the top-view perspective, and comprising a second input terminal and a second output terminal; and a second photoelectric layer, disposed between the second input terminal and the second output terminal.

In accordance with some embodiments of the disclosure, a method for manufacturing a semiconductor structure is provided. The method may include several operations. A semiconductor layer of a substrate is patterned, and thereby an optical structure is formed over the substrate. A first doping region, a second doping region and a third doping region are formed, wherein the first doping region is disposed in the optical structure, the second doping region is disposed adjacent to the first doping region in the optical structure, and the third doping region of a transistor is disposed in the semiconductor layer separated from the optical structure. A photoelectric material is formed proximal to a junction of the first doping region and the second doping region. At least a first contact is formed over the optical structure and at least a second contact is formed over the transistor. An interconnect structure is formed over the optical structure and the transistor to electrically connect the optical structure and the transistor.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

It should be noted that, in the operation 802, the doping regions 41, 42, 43 and 44 can be formed together with or concurrently with one or more doping regions or well regions of the transistor 101, and the above illustration is not intended to limit the present disclosure. In other embodiments, one of the doping regions 41, 42, 43, 44 can be formed together with a body well region, a deep well region, an active region, or other doped region of the transistor or other areas of the semiconductive material layer 113 other than the detecting structure 4. Details of the process can be adjusted depending on different applications.

It should be noted that the operations of the method 700 and/or the method 800 are able to be rearranged or otherwise modified within the scope of the various aspects. In some embodiments, additional processes are provided before, during, and after the method 700 and/or the method 800, and some other processes are only briefly described herein. Thus, other implementations are possible within the scope of the various aspects described herein.

Aspects of this description relate to a semiconductor structure. The semiconductor structure includes a waveguide structure on a substrate. The waveguide structure includes a first protrusion having a first dopant type having a first dopant concentration. The waveguide structure further includes a first lower portion having the first dopant type having a second dopant concentration different from the first dopant concentration. The waveguide structure further includes a second lower portion having a second dopant type having a third dopant concentration, wherein the second dopant type is different from the first dopant type, and an interface of the first lower portion and the second lower portion defines a PN interface. The waveguide structure further includes a second protrusion having the second dopant type having a fourth dopant concentration different from the third dopant concentration. The semiconductor structure includes a photoelectric material proximate the PN interface, wherein the photoelectric material extends above the PN interface. In some embodiments, the semiconductor structure further includes a first high concentration region between the first protrusion and the first lower portion, wherein the first high concentration region has the first dopant type and a dopant concentration of the first high concentration region is greater than each of the first dopant concentration and the second dopant concentration. In some embodiments, a top surface of the first high concentration region is coplanar with a top surface of the first protrusion. In some embodiments, a top surface of the first high concentration region is coplanar with a top surface of the first lower portion. In some embodiments, the semiconductor structure further includes a second high concentration region between the second protrusion and the second lower portion, wherein the second high concentration region has the second dopant type and a dopant concentration of the second high concentration region is greater than each of the third dopant concentration and the fourth dopant concentration. In some embodiments, a top surface of the second high concentration region is coplanar with a top surface of the second protrusion. In some embodiments, a top surface of the second high concentration region is coplanar with a top surface of the second lower portion. In some embodiments, the semiconductor structure further includes a third protrusion, wherein the third protrusion has both the first dopant type and the second dopant type, and the PN interface extends into the third protrusion. In some embodiments, an entirety of the photoelectric material is above the third protrusion. In some embodiments, the photoelectric material extends along sidewalls of the third protrusion. In some embodiments, a first portion of the third protrusion has the first dopant type and the second dopant concentration. In some embodiments, a second portion of the third protrusion has the second dopant type and the third dopant concentration. In some embodiments, a bottommost surface of the photoelectric material is below a top surface of the first lower portion. In some embodiments, an intrinsic region is between the photoelectric material and the PN interface, wherein the intrinsic region is free of dopant implants.

Aspects of this description relate to a semiconductor structure. The semiconductor structure includes a waveguide structure on a substrate. The waveguide structure includes a first protrusion having a first dopant type; a first lower portion having the first dopant type; a second lower portion having a second dopant type, wherein the second dopant type is different from the first dopant type, and an interface of the first lower portion and the second lower portion defines a PN interface; and a second protrusion having the second dopant type. The semiconductor structure further includes a photoelectric material proximate the PN interface, wherein the photoelectric material extends above the PN interface. The semiconductor structure further includes a first electrical contact electrically connected to the first protrusion. The semiconductor structure further includes a second electrical contact electrically connected to the second protrusion. In some embodiments, the semiconductor structure further includes a high-k layer over the photoelectric material, a top surface of the first lower portion, and a sidewall of the first protrusion. In some embodiments, the semiconductor structure includes a silicide layer between the first electrical contact and the first protrusion. In some embodiments, the semiconductor structure further includes an interconnect structure electrically connected to the first electrical contact and the second electrical contact. In some embodiments, the semiconductor structure further includes a transistor, wherein the transistor is electrically connected to the interconnect structure.

Aspects of this description relate to a method of making a semiconductor structure. The method includes patterning a waveguide material to define a first protrusion having a first height, a first lower portion having a second height less than the first height, a second lower portion having the second height, and a second protrusion having the first height. The method further includes doping the first protrusion with a first dopant type to have a first dopant concentration. The method further includes doping the first lower portion with the first dopant type to have a second dopant concentration different from the first dopant concentration. The method further includes doping the second lower portion with a second dopant type, different from the first dopant type, to have a third dopant concentration. The method further includes doping the second protrusion with the second dopant type to have a fourth dopant concentration different from the third dopant concentration. The method further includes forming a photoelectric material proximate an interface between the first lower portion and the second lower portion.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a waveguide structure on a substrate, wherein the waveguide structure comprises:
a first protrusion having a first dopant type having a first dopant concentration;
a first lower portion having the first dopant type having a second dopant concentration different from the first dopant concentration;
a second lower portion having a second dopant type having a third dopant concentration,
wherein the second dopant type is different from the first dopant type, and an interface of the first lower portion and the second lower portion defines a PN interface; and
a second protrusion having the second dopant type having a fourth dopant concentration different from the third dopant concentration; and
a photoelectric material proximate the PN interface, wherein the photoelectric material extends above the PN interface.

2. The semiconductor device of claim 1, further comprising a first high concentration region between the first protrusion and the first lower portion, wherein the first high concentration region has the first dopant type and a dopant concentration of the first high concentration region is greater than each of the first dopant concentration and the second dopant concentration.

3. The semiconductor device of claim 2, wherein a top surface of the first high concentration region is coplanar with a top surface of the first protrusion.

4. The semiconductor device of claim 2, wherein a top surface of the first high concentration region is coplanar with a top surface of the first lower portion.

5. The semiconductor device of claim 2, further comprising a second high concentration region between the second protrusion and the second lower portion, wherein the second high concentration region has the second dopant type and a dopant concentration of the second high concentration region is greater than each of the third dopant concentration and the fourth dopant concentration.

6. The semiconductor device of claim 5, wherein a top surface of the second high concentration region is coplanar with a top surface of the second protrusion.

7. The semiconductor device of claim 5, wherein a top surface of the second high concentration region is coplanar with a top surface of the second lower portion.

8. The semiconductor device of claim 1, further comprising a third protrusion, wherein the third protrusion has both the first dopant type and the second dopant type, and the PN interface extends into the third protrusion.

9. The semiconductor device of claim 8, wherein an entirety of the photoelectric material is above the third protrusion.

10. The semiconductor device of claim 8, wherein the photoelectric material extends along sidewalls of the third protrusion.

11. The semiconductor device of claim 8, wherein a first portion of the third protrusion has the first dopant type and the second dopant concentration.

12. The semiconductor device of claim 11, wherein a second portion of the third protrusion has the second dopant type and the third dopant concentration.

13. The semiconductor device of claim 1, wherein a bottommost surface of the photoelectric material is below a top surface of the first lower portion.

14. The semiconductor device of claim 13, wherein an intrinsic region is between the photoelectric material and the PN interface, wherein the intrinsic region is free of dopant implants.

15. A semiconductor structure, comprising:
a waveguide structure on a substrate, wherein the waveguide structure comprises:
a first protrusion having a first dopant type;
a first lower portion having the first dopant type;
a second lower portion having a second dopant type, wherein the second dopant type is different from the first dopant type, and an interface of the first lower portion and the second lower portion defines a PN interface; and
a second protrusion having the second dopant type;
a photoelectric material proximate the PN interface, wherein the photoelectric material extends above the PN interface;
a first electrical contact electrically connected to the first protrusion; and
a second electrical contact electrically connected to the second protrusion.

16. The semiconductor structure of claim 15, further comprising a high-k layer over the photoelectric material, a top surface of the first lower portion, and a sidewall of the first protrusion.

17. The semiconductor structure of claim 15, further comprising a silicide layer between the first electrical contact and the first protrusion.

18. The semiconductor structure of claim 15, further comprising an interconnect structure electrically connected to the first electrical contact and the second electrical contact.

19. The semiconductor structure of claim 18, further comprising a transistor, wherein the transistor is electrically connected to the interconnect structure.

20. A method of making a semiconductor structure, the method comprising:
patterning a waveguide material to define:
a first protrusion having a first height,
a first lower portion having a second height less than the first height,
a second lower portion having the second height, and
a second protrusion having the first height;
doping the first protrusion with a first dopant type to have a first dopant concentration;
doping the first lower portion with the first dopant type to have a second dopant concentration different from the first dopant concentration;
doping the second lower portion with a second dopant type, different from the first dopant type, to have a third dopant concentration;
doping the second protrusion with the second dopant type to have a fourth dopant concentration different from the third dopant concentration; and
forming a photoelectric material proximate an interface between the first lower portion and the second lower portion.
